(19) United States
(12) Patent Application Publication
(10) Pub. No.: US 2026/0282719 A1
(43) Pub. Date: Sep. 17, 2026

(54) LIGHT EMITTING DEVICE, DISPLAY DEVICE, PHOTOELECTRIC CONVERSION DEVICE, ELECTRONIC APPARATUS, ILLUMINATION DEVICE, AND MOVING BODY

(71) Applicant: CANON KABUSHIKI KAISHA, Tokyo (JP)

(72) Inventors: TASUKU KANEDA, Kanagawa (JP); NORIFUMI KAJIMOTO, Kanagawa (JP); SHOMA HINATA, Kanagawa (JP); RYOTA KANESHIMA, Kanagawa (JP); YUSUKE KIDA, Kanagawa (JP)

(21) Appl. No.: 19/559,504

(22) Filed: Mar. 6, 2026

(30) Foreign Application Priority Data
Mar. 13, 2025 (JP) 2025-040485

(51) Int. Cl. H10K 59/80; H10K 50/12; H10K 59/12; H10K 102/00

(52) U.S. Cl. CPC H10K 59/878; H10K 50/12; H10K 59/1201; H10K 2102/351

(57) ABSTRACT

A device including pixels is provided. Each pixel includes a first electrode, a second electrode between the first electrode and a substrate, an organic layer between the first and second electrodes, a reflector between the second electrode and the substrate, and an insulator between the second electrode and the reflector. The second electrode includes a first portion contacting the organic layer, and the insulator includes a second portion contacting the first portion. In a first pixel of the pixels, a thickness of the first portion is larger than that of the second portion, the organic layer contains a light emitting dopant, and in a case where λ, φ, and L indicate a PL peak wavelength of the dopant, a sum of phase shifts in the reflector and the first electrode, and an optical distance between the reflector and the first electrode, (λ/8)(−(2φ/π)−1)<L<(λ/8)(−(2φ/π)+1) is satisfied.

### BACKGROUND

### Field of the Technology

The present disclosure relates to a light emitting device, a display device, a photoelectric conversion device, an electronic apparatus, an illumination device, and a moving body.

### Description of the Related Art

A light emitting device including a light emitting element such as an organic electroluminescence (EL) element is known. Japanese Patent Laid-Open No. 2021-072282 describes an organic device including an optical resonance structure in which a reflective film is arranged between a lower electrode and a substrate, and the distance between an upper electrode and the reflective film is changed in accordance with the color of light to be emitted, thereby amplifying light at the resonant wavelength corresponding to each light emission color.

In order to further improve the light emission efficiency and view angle characteristic of the light emitting device including the optical resonance structure, it is effective to reduce the interference order of optical interference in the optical resonance structure. To reduce the interference order, thinning respective layers such as an optical adjustment layer, the lower electrode, and an organic functional layer, which are arranged between the reflective film and the upper electrode, is conceivable.

### SUMMARY

If the lower electrode is thinned, the electric resistance in the lower electrode increases, and this can lead to the increase of power consumption of the light emitting device.

One aspect of the present disclosure provides a technique advantageous in improving display characteristic and suppressing the increase of power consumption.

According to some embodiments, a light emitting device in which a plurality of pixels including a first pixel are arranged on a main surface of a substrate, wherein each of the plurality of pixels includes a first electrode, a second electrode arranged between the first electrode and the substrate, an organic functional layer arranged between the first electrode and the second electrode, a reflective layer arranged between the second electrode and the substrate, and an insulating layer arranged between the second electrode and the reflective layer, the second electrode includes a first portion contacting the organic functional layer, and the insulating layer includes a second portion contacting the first portion, in the first pixel, a film thickness of the first portion is larger than a film thickness of the second portion, in the first pixel, the organic functional layer includes a light emitting layer containing a light emitting dopant, and in a case where λ indicates a PL peak wavelength of the light emitting dopant, φ indicates a sum of a phase shift φr upon reflection in the reflective layer and a phase shift φs upon reflection in the first electrode (φ<0), and L indicates an optical distance between the reflective layer and the first electrode, (λ/8)×(−(2φ/π)−1)<L<(λ/8)×(−(2φ/π)+1) is satisfied, is provided.

Features of the present disclosure will become apparent from the following description of embodiments with reference to the attached drawings. The following description of embodiments is described by way of example.

### BRIEF DESCRIPTION OF THE DRAWINGS

FIGS. 1A to 1C are plan views each showing an example of the configuration of a light emitting device according to an embodiment;

FIG. 2 is a sectional view showing an example of the configuration of the light emitting device shown in FIG. 1A;

FIGS. 3A to 3D are views showing an example of a manufacturing method of the light emitting device according to the embodiment;

FIGS. 4A to 4C are views showing the example of the manufacturing method of the light emitting device according to the embodiment;

FIGS. 5A to 5C are views showing the example of the manufacturing method of the light emitting device according to the embodiment;

FIGS. 6A to 6C are views showing the example of the manufacturing method of the light emitting device according to the embodiment;

FIGS. 7A and 7B are views showing the example of the manufacturing method of the light emitting device according to the embodiment;

FIG. 8 is a view showing the example of the manufacturing method of the light emitting device according to the embodiment;

FIG. 9 is a sectional view showing an example of the configuration of a light emitting device of a comparative example;

FIG. 10 is a sectional view showing an example of the configuration of the light emitting device according to the embodiment;

FIG. 11 is a sectional view showing an example of the configuration of the light emitting device according to the embodiment;

FIG. 12 is a sectional view showing an example of the configuration of the light emitting device according to the embodiment;

FIG. 13 is a sectional view showing an example of the configuration of the light emitting device according to the embodiment;

FIGS. 14A and 14B are sectional views showing an example of the configuration of a pixel of the light emitting device according to the embodiment;

FIGS. 15A to 15C are views showing an example of an image forming device using the light emitting device according to the embodiment;

FIG. 16 is a view showing an example of a display device using the light emitting device according to the embodiment;

FIG. 17 is a view showing an example of a photoelectric conversion device using the light emitting device according to the embodiment;

FIG. 18 is a view showing an example of an electronic apparatus using the light emitting device according to the embodiment;

FIGS. 19A and 19B are views each showing an example of a display device using the light emitting device according to the embodiment;

FIG. 20 is a view showing an example of an illumination device using the light emitting device according to the embodiment;

FIGS. 21A and 21B are views showing an example of a moving body using the light emitting device according to the embodiment;

FIGS. 22A and 22B are views each showing an example of a wearable device using the light emitting device according to the embodiment; and

FIGS. 23A and 23B are views showing an example of a head mounted display using the light emitting device according to the embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

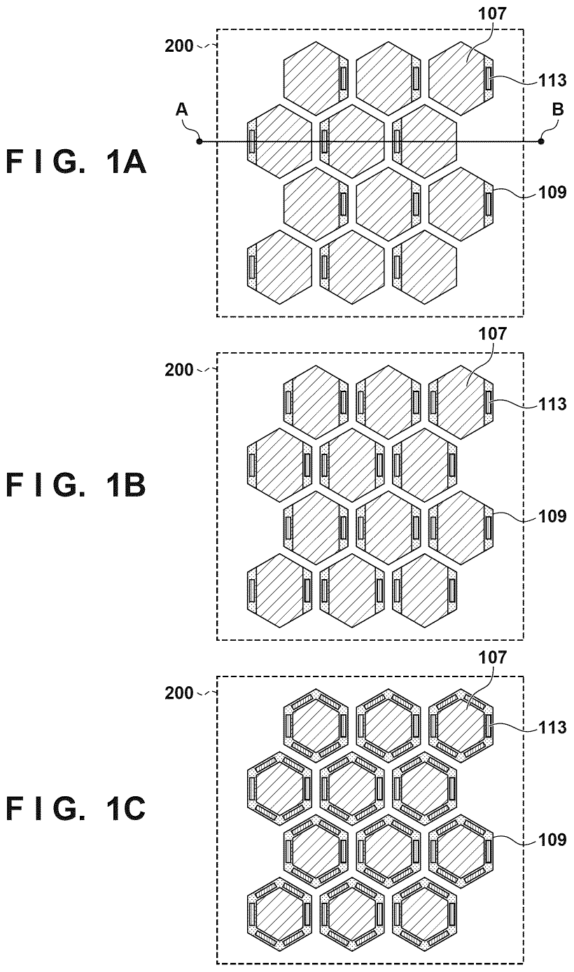

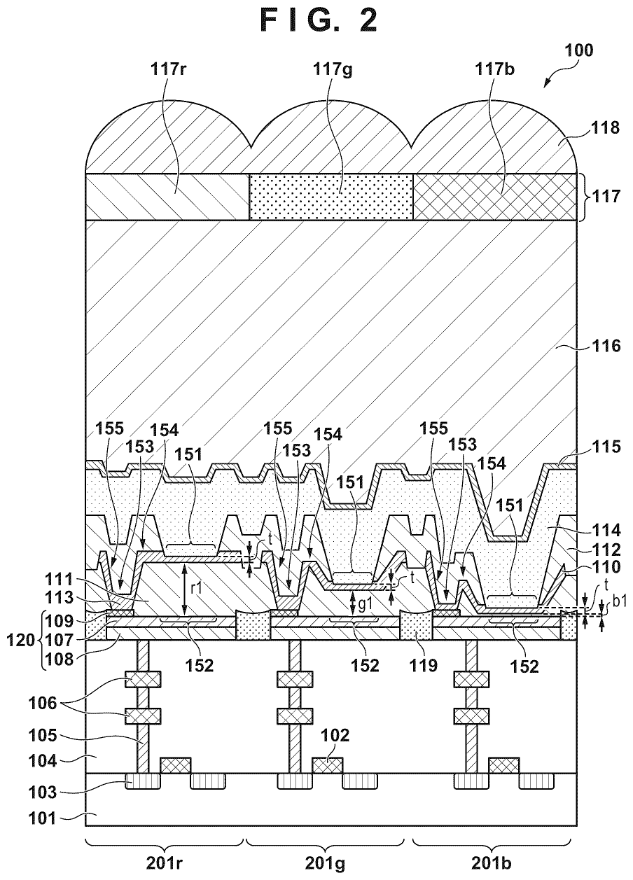

With reference to FIGS. 1A to 13, a light emitting device according to an embodiment of the present disclosure will be described. FIGS. 1A to 1C are plan views each showing an example of the configuration of a light emitting device 100 according to this embodiment, and FIG. 2 is a sectional view showing an example of the configuration taken along a line A-B in FIG. 1A.

In the light emitting device 100, a plurality of pixels 201 are arranged on the main surface of a substrate 101. Each of the plurality of pixels 201 includes an electrode 115, an electrode 110 arranged between the electrode 115 and the substrate 101, an organic functional layer 114 arranged between the electrode 115 and the electrode 110, a reflective layer 107 arranged between the electrode 110 and the substrate 101, and an insulating layer 111 arranged between the electrode 110 and the reflective layer 107. The electrode 115 can also be called an upper electrode. The electrode 110 can also be called a lower electrode. The electrode 115 may function as a cathode, and the electrode 110 may function as an anode. Alternatively, the electrode 110 may function as a cathode, and the electrode 115 may function as an anode. Each of the plurality of pixels 201 can include a metal layer 109 arranged between the electrode 110 and the reflective layer 107 and contacting the electrode 110 and the reflective layer 107, and a metal layer 108 arranged between the reflective layer 107 and the substrate 101 and contacting the reflective layer 107. The metal layer 109, the reflective layer 107, and the metal layer 108 constitute a pixel electrode 120 connected to the electrode 110. Each of FIGS. 1A to 1C shows the reflective layer 107 and the metal layer 109 constituting the pixel electrode 120, and a contact region 113 where the metal layer 109 and the electrode 110 are in contact with each other, which are arranged in a pixel region 200. The planar layout patterns shown in FIGS. 1A to 1C are not limited to these, and can be combined or changed.

In this embodiment, the reflective layer 107 and the metal layer 109 are formed and electrically isolated for each pixel 201. The shape of the reflective layer 107 is not limited to a hexagon as shown in FIGS. 1A to 1C, and may be another polygon or a circle. The sizes of the reflective layers 107 in the respective pixels 201 may be the same as shown in FIGS. 1A to 1C, or may be different. For example, the sizes of the reflective layers 107 in the pixels 201 may be different from each other in accordance with the color to be emitted.

The contact region 113 is a region for electrically connecting the electrode 110 to a wiring layer or the like arranged below the electrode 110, and the metal layer 109 is in contact with the electrode 110 in the contact region 113. By adopting this structure, any metal can be selected that has a low contact resistance between the metal layer 109 and the electrode 110, regardless of the material of the reflective layer 107. For example, copper-containing aluminum (AlCu: for example, Al doped with 0.5 at % of Cu) may be used for the reflective layer 107, indium tin oxide (ITO) may be used for the electrode 110, and titanium nitride (TiN) may be used for the metal layer 109. In this case, high reflectance is realized in the reflective layer 107 while the contact resistance between the electrode 110 and the metal layer 109 is low. This can contribute to the decrease of the power consumption of the light emitting device 100. In this embodiment, the metal layer 109 is electrically connected to the reflective layer 107.

In the configuration shown in FIG. 1A, one reflective layer 107 is provided with one metal layer 109, and one metal layer 109 is provided with one contact region 113. Alternatively, one reflective layer 107 may be provided with a plurality of metal layers 109 and contact regions 113 as shown in FIG. 1B, or the density or area of the contact region 113 may be changed as shown in FIG. 1C. In the configuration shown in FIG. 1A, the surface of at least a part of the outer edge portion of the reflective layer 107, which faces the side opposite to the substrate 101, is in contact with the insulating layer 111. With this, the ratio of the reflective layer 107 in the pixel 201 increases, so that the area contributing to light emission increases. Accordingly, the luminance of the pixel 201 can be improved. On the other hand, in the configurations shown in FIGS. 1B and 1C, the ratio of the contact region 113 can be increased. This can suppress the increase of power consumption caused by the increase of the contact resistance. This also has an effect of suppressing color mixing between the adjacent pixels 201. In accordance with the specifications required for the light emitting device 100, the area of the reflective layer 107 exposed to the insulating layer 111, the area, shape, and number of the metal layers 109 and the contact regions 113, and the like may respectively be set. By providing the contact region 113, the reflective layer 107, and the metal layer 109, the light emitting device 100 that achieves different signal intensity for each pixel 201 and the interference condition can be formed. Considering light reflection at the reflective layer 107 and color mixing between the pixels 201, the metal layer 109 (contact region 113) can be arranged in the outer edge portion of the reflective layer 107.

FIG. 2 shows three pixels 201r, 201g, and 201b. Hereinafter, when indicating a specific pixel among the pixels 201, a suffix such as “r” of the pixel 201r will be added following the reference numeral, and when indicating any of the pixels 201, it will be simply indicated as the pixel “201”. This applies to other components in a similar manner. The pixel 201 is arranged on the substrate 101 using a semiconductor such as silicon (Si). The substrate 101 is arranged with a gate oxide film, a gate electrode 102, an impurity region 103, and the like constituting a transistor configured to drive the light emitting element including the electrodes 110 and 115 and the organic functional layer 114, and the like. The substrate 101 is also arranged with an element isolation region (for example, STI) or the like. For example, a silicon substrate may be used as the substrate 101. Alternatively, for example, a semiconductor layer made of silicon or the like may be arranged on an insulating substrate made of glass, a plastic, or the like, and the transistor and the like may be arranged in the semiconductor layer.

An interlayer insulating layer 104 is arranged on the substrate 101, and wiring patterns 106 are arranged in the interlayer insulating layer 104. Contact plugs 105 provide electrical connections between the gate electrode 102 and the wiring pattern 106, between the impurity region 103 and the wiring pattern 106, and between the wiring patterns 106 in different wiring layers. For the interlayer insulating layer 104, for example, borophosphosilicate glass (BPSG) deposited using a thermal chemical vapor deposition (thermal CVD) method or the like, silicon oxide (SiO) deposited using a plasma CVD method, or the like can be used. For the wiring pattern 106, Al, Cu, or the like can be used. For example, a wiring layer where the wiring pattern 106 using Al is arranged and a wiring layer where the wiring pattern 106 using Cu is arranged may be mixed. Between the wiring pattern 106 and the interlayer insulating layer 104, a barrier metal layer using titanium (Ti), TiN, tantalum (Ta), tantalum nitride (TaN), or the like may be arranged. For the contact plug 105, tungsten (W) or the like can be used. Between the contact plug 105 and the interlayer insulating layer 104, a barrier metal layer made of Ti/TiN or the like may be arranged.

The pixel electrode 120 is arranged on the interlayer insulating layer 104. The pixel electrode 120 can be formed by a stacked structure of the metal layer 108, the reflective layer 107, and the metal layer 109. For the metal layer 108 and the metal layer 109, for example, Ti, TiN, a titanium alloy, Ta, a tantalum alloy, or the like can be used. For the reflective layer 107, Al, AlCu, an aluminum alloy including an aluminum-nickel alloy (Al—Ni), silver (Ag), an Ag alloy, or the like can be used.

The metal layer 108 is required to be capable of decreasing the contact resistance with the contact plug 105. Since the reflective layer 107 is formed on the metal layer 108 so as to be in contact with the metal layer 108, the crystal orientation property of the metal layer 108 has a significant influence on the orientation property of the reflective layer 107. The orientation property of the reflective layer 107 is influenced by the grain size and the density of grain boundaries of the metal layer 108, and the reflectance changes when the unevenness of the surface of the reflective layer 107 changes. In addition, the crystal orientation property of the metal layer 108 also has an influence on electromigration and reliability. The metal layer 108 may be made of only one of the above-described materials, or may be formed by a stacked structure of these materials. For example, when a stacked structure of a Ti layer having a thickness of 20 nm or more and 80 nm or less and a TiN layer having a thickness of 10 nm or more and 40 nm or less is used as the metal layer 108, the orientation properties of the Ti layer and the TiN layer can be improved. The metal layer 108 may be formed to have a film thickness of, for example, 40 nm or more and 100 nm or less. If the metal layer 108 is thinned, the orientation property of the metal layer 108 deteriorates and may affect the orientation property of the reflective layer 107. When forming the metal layer 108 by a sputtering method, the orientation property of the metal layer 108 can be improved by adjusting the target-substrate distance to a long distance, using a substrate bias application type sputtering method, and adjusting the substrate temperature.

By using a metal having high reflectance and low resistivity for the reflective layer 107, the light emission efficiency of the optical resonance structure can be improved. The reflective layer 107 may be made of only one of the above-described materials, or may be formed by a stacked structure of these materials. AlCu as a material having a high reflectance in a visible light region may be used for the reflective layer 107. Improving the reflectance can contribute to improvement in light emission efficiency per unit area of the pixel 201. This embodiment is directed to alight emitting element (pixel 201) in which the interference order of the optical interference structure is reduced to improve the light emission efficiency and view angle characteristic. In this case, since the light generated in the organic functional layer 114 undergoes multiple reflection between the reflective layer 107 and the electrode 115, the effect of the reflectance of the reflective layer 107 on the light emission efficiency per unit area of the light emitting element (pixel 201) increases. The reflective layer 107 may be formed to have a film thickness of, for example, about 100 nm or more and 600 nm or less. In this case, the reflective layer 107 itself can also serve as an electrode pad for voltage application to the light emitting element. This eliminates the need to additionally form a wiring layer (wiring pattern) for the electrode pad, so that the manufacturing cost of the light emitting device 100 can be reduced.

The metal layer 109 is required to have a low resistance contact not only with the reflective layer 107 but also with the electrode 110. When TiN is applied to the metal layer 109 and ITO is applied to the electrode 110, a low resistance contact between the metal layer 109 and the electrode 110 can be obtained in the contact region 113.

The electrode 110 formed around the contact region 113 is arranged on the step of the insulating layer 111 formed during manufacturing, as will be described in detail later. The electrode 110 may be thinned due to this step, so that the electrode 110 can be stepped cut or the resistance thereof can increase. To prevent this, like the pixels 201g and 201b shown in FIG. 2, the step formed due to the insulating layer 111 may be lower between the contact region 113 and the region where the electrode 110 and the organic functional layer 114 are in contact with each other than between the pixels 201. Here, as shown in FIG. 2, a portion of the electrode 110 which is in contact with the organic functional layer 114 is a portion 151, a portion which is in contact with the metal layer 109 is a portion 153, a portion located between the portion 151 and the portion 153 is a portion 154, and a portion located between the portion 153 and the outer edge of the electrode 110 is a portion 155. In this case, the insulating layer 111 can be formed so that the portion 155 includes a portion which is higher than the portion 154 from the substrate 101, as in the pixels 201g and 201b shown in FIG. 2. This can suppress thinning of the electrode 110 in the portion 154, thereby suppressing occurrence of the step-cut or the increase of the resistance. Furthermore, since the metal layer 109 is arranged above the reflective layer 107, a step is generated between the reflective layer 107 and the metal layer 109. The step between the reflective layer 107 and the metal layer 109 can have an influence on the shape (for example, the tapered shape) of an opening provided in the insulating layer 111 to form the contact region 113 where the electrode 110 is in contact with the metal layer 109. Depending on the shape of the opening, the electrode 110 itself may become thin and have a high resistance, or the organic functional layer 114 may become thin and cause leakage between the electrode 110 and the electrode 115, resulting in the increase of power consumption. Therefore, the film thickness of the metal layer 109 may be within a range of 10 nm (inclusive) to 60 nm (inclusive).

As described above, in the pixel electrode 120, the reflective layer 107 can be formed using a material having a lower specific resistance and a higher reflectance than the metal layers 108 and 109. Therefore, the metal layers 108 and 109 can be formed thinner than the reflective layer 107. The metal layer 109 is designed to have a smaller film thickness than the metal layer 108. This can improve the characteristics of the light emitting device 100.

The pixel electrode 120 is formed separately for each pixel 201. Between the pixel electrodes 120 of the pixels 201, an isolating insulating portion 119 is arranged. For the isolating insulating portion 119, SiO, silicon nitride (SiN), silicon oxynitride (SiON), silicon oxycarbide (SiOC), silicon carbonitride (SiCN), or the like can be used. The isolating insulating portion 119 may have a single layer structure made of the material as described above, or may have a stacked structure in which layers of these materials are stacked. The isolating insulating portion 119 insulates the adjacent pixel electrodes 120 from each other. The isolating insulating portion 119 may function as an etching stopper when patterning the insulating layer 111 and the electrodes 110.

On the reflective layers 107, the insulating layer 111 having different film thicknesses in the pixel 201r, the pixel 201g, and the pixel 201b is arranged. More specifically, a portion 152 of the insulating layer 111, which is in contact with the portion 151 of the electrode 110 contacting the organic functional layer 114, has different thicknesses for the pixel 201r, the pixel 201g, and the pixel 201b. The insulating layer 111 can also be called an optical adjustment layer. The film thickness of the portion 152 of the insulating layer 111 is a thickness r1 in the pixel 201r, a thickness g1 in the pixel 201g, and a thickness b1 in the pixel 201b. In this embodiment, a relationship expressed by r1>g1>b1 is provided. For example, the pixel 201r can emit red light, the pixel 201g can emit green light, and the pixel 201b can emit blue light. It can also be said that the pixels 201r and 201g are pixels each of which emits light with a longer peak wavelength than the peak wavelength of light emitted by the pixel 201b. Similarly, it can also be said that the pixel 201r is a pixel that emits light with a longer peak wavelength than the peak wavelength of light emitted by the pixel 201g. The peak wavelength can be, for example, the wavelength at which the luminance has the maximum value when the abscissa represents the wavelength of light emitted by the pixel 201 and the ordinate represents the luminance thereof. The film thickness of the insulating layer 111 of each pixel 201 can be changed in accordance with the design of the resonant wavelength of the pixel 201. With this, the optical resonance structure is formed between the reflective layer 107 and the electrode 115 for each pixel 201. In the optical resonance structure having a different height for each pixel 201, light emission with the luminance amplified at the resonant wavelength can be obtained. For example, SiO or the like can be used for the insulating layer 111. SiO can be suitable for the insulating layer 111 because it has a low refractive index and a high light transmittance. For example, a material having a refractive index of 1.6 or less may be used for the insulating layer 111.

Details of the film thickness design of the insulating layer 111 will be described later. Note that the thickness b1 of the portion 152 of the insulating layer 111 in the pixel 201b may be formed within a range of 0.5 nm (inclusive) to 5 nm (inclusive). This is due to the following two reasons.

The first reason is to ensure the flatness of the electrode 110. As described above, for the reflective layer 107, AlCu or the like can be used as a material having a high reflectance in a visible light region. Consider a case where ITO, which is to be used as the electrode 110, is deposited on the surface of AlCu using a sputtering method or the like. Since the melting point of indium or tin is low, due to the substrate temperature, ITO to be attached to the substrate is deposited through the droplet state of indium or tin. It is known that, in a deposition mode through a droplet state, since the surface free energy is low on the surface of AlCu, the surface wettability is low and droplets are less likely to spread, thereby causing growth of spike-like protrusions. If spike-like protrusions of the electrode 110 are generated, when the organic functional layer 114 is thinned, leakage occurs between the electrode 110 and the electrode 115. Thus, power consumption can increase. In this embodiment, as a method for suppressing deposition abnormality such as spike-like protrusions of the electrode 110, the insulating layer 111 using SiO is formed on the surface of the reflective layer 107, and ITO to be used as the electrode 110 is deposited on SiO. This can suppress abnormal growth of the spike-like protrusions of the electrode 110. In the sputtering process, to prevent contact between the reflective layer 107 and the electrode 110, the insulating layer 111 needs to ensure a film thickness of 0.5 nm or more.

The second reason is to suppress the increase of the resistance of the electrode 110. The thickness b1 of the portion 152 of the insulating layer 111 in the pixel 201b is a part of the optical path length of the optical interference structure. Therefore, if the thickness b1 is increased, the portion 151 of the electrode 110 needs to be thinned to match the interference in the pixel 201b. Since the electrode 110 is a layer where charges are directly injected to the organic functional layer 114, the increase of the resistance of the electrode 110 influences the luminance and power consumption. Hence, in the pixel 201 where the interference order of the optical interference structure is reduced, making the thickness of the portion 151 of the electrode 110 relatively larger than the thickness b1 of the portion 152 of the insulating layer 111 can be a necessary requirement.

On the other hand, the thicknesses r1 and g1 of the portions 152 of the insulating layer 111 in the pixels 201r and 201g, respectively, may be formed larger than the film thickness of the portion 151 of the electrode 110. This is because, for the pixels 201r and 201g, the thicknesses r1 and g1 are designed to be larger than the thickness b1 to form the optical interference structures on the side of a longer wavelength than the pixel 201b. Furthermore, by forming the electrode 110 so as to have the same film thickness in the pixels 201, it is possible to suppress variations in power consumption and luminance among colors.

As a method for forming the insulating layer 111 on the pixel 201b, an atomic layer deposition (ALD) method or the like may be used. Due to oxidation of aluminum, aluminum oxide may be formed on the surface of AlCu to be used as the reflective layer 107. The refractive index of aluminum oxide is as high as 1.8 or more, and this can affect the optical interference shift. To prevent this, the insulating layer 111 using thin SiO having a refractive index of 1.6 or less is formed on the surface of AlCu by using the ALD method or the like. Thus, a uniform thin insulating layer can be formed on the reflective layer 107.

The insulating layer 111 is not limited to SiO described above, and may be formed by appropriately selecting or combining materials such as SiN and SiON each having a high light transmittance. Alternatively, for example, for the insulating layer 111 serving as the optical adjustment layer, a conductive material such as ITO or indium zinc oxide (IZO) having a high light transmittance may be used. The insulating layer 111 may have a single layer structure using a layer of the material described above, or may have a stacked structure. For example, the pixels 201 may have different configurations.

A bank 112 for defining a light emitting region (a region where the electrode 110 and the organic functional layer 114 are in contact with each other) is arranged on the insulating layer 111. The electrode 110 can be, for example, an electrode film made of ITO, IZO, or the like having a high light transmittance. The refractive index of the electrode 110 can be, for example, 1.4 or more. The film thickness of the electrode 110 may be formed within a range of 5 nm (inclusive) to 20 nm (inclusive) in the portion 151 to suppress the increase of the resistance as described above. In each pixel 201, the film thickness of the portion 153 of the electrode 110 contacting the metal layer 109 may be larger than the film thickness of the portion 151 contacting the organic functional layer 114. In this case, the film thickness of a conductor increases in the contact region 113 where the metal layer 109 and the electrode 110 are in contact with each other. As a result, the contact resistance can be decreased. In addition, by adjusting the film thickness of the electrode 110 in accordance with the film thickness of the insulating layer 111, the processing controllability of the optical interference structure improves. Hence, the film thickness of the portion 151 of the electrode 110 may be more than twice and less than ten times the film thickness of the insulating layer 111. This configuration can suppress the increase of the resistance in the electrode 110 while suppressing abnormal deposition that causes the spike-like protrusions of the electrode 110. For example, as shown in FIG. 2, in each pixel 201, the film thickness of the portion 151 of the electrode 110 contacting the organic functional layer 114 may be smaller than the film thickness of the portion adjacent to the portion 151. Since the portion 151 of the electrode 110 influences the optical interference, it needs to have a predetermined thickness. On the other hand, by increasing the film thickness of the portion 154 of the electrode 110 connecting the portion 151 and the portion 153, the increase of the resistance can be suppressed. For example, when performing etching to form the bank 112, a portion to be the portion 151 of the electrode 110 is etched together with the material layer of the bank 112 to make the film thickness of the portion adjacent to the portion 151 larger than that of the portion 151. For the bank 112, for example, SiO or the like is used.

The organic functional layer 114 is arranged on the electrode 110. The organic functional layer 114 contains at least an organic light emitting material, and may include, for example, a charge transport layer, a charge blocking layer, a carrier generation layer, and the like as additional functional layers. The electrode 115 is arranged on the organic functional layer 114. The electrode 115 is translucent. The material of the electrode 115 may be a semi-transmissive material having a property of transmitting part of light that has reached the surface of the electrode 115 and reflecting the remaining part of the light (that is, a semi-transmissive reflective property). As the material of the electrode 115, for example, a transparent material such as ITO or IZO may be used. As the material of the electrode 115, a semi-transmissive material such as Al, Ag, gold (Au), platinum (Pt), chromium (Cr), an alkali metal (lithium (Li), cesium (Cs), or the like), an alkaline earth metal (magnesium (Mg), calcium (Ca), barium (Ba), or the like), or an alloy material containing these metal materials may be used.

A sealing layer 116 is arranged on the electrode 115. The sealing layer 116 is translucent, and suppresses permeation of water into the substrate 101, the organic functional layer 114, the electrode 115, and the like from the outside of the light emitting device 100. The sealing layer 116 may have a stacked structure containing SiN, SiON, SiO, aluminum oxide (Al₂O₃), and the like deposited using a plasma CVD method, an ALD method, a sputtering method, or the like, or may have a signal layer structure as long as it has sufficient water block performance. Furthermore, the sealing layer 116 may include an organic layer made of a resin or the like as long as it has appropriate water block performance. For example, polyacrylate, polyimide, polyester, epoxy, or the like may be used for the sealing layer 116.

Color filters 117 can be arranged on the sealing layer 116. In this embodiment, a color filter 117r can transmit red light, a color filter 117g can transmit green light, and a color filter 117b can transmit blue light. A microlens 118 can be arranged on the color filter 117. The microlens 118 may be formed in a uniform shape across the entire pixel region 200, or the microlens 118 with partially different curvatures may be formed.

Next, the film thickness design of the optical interference structure of the light emitting device 100 will be described. In this embodiment, by setting the film thickness of the organic functional layer 114 so as to achieve high luminance particularly in the front direction, the light emission color is also controlled by the optical interference, and light is emitted in the front direction with higher efficiency. More specifically, by setting an interference order i to adjust an optical distance d0 from the light emitting position of the light emitting layer of the organic functional layer 114 to the respective reflecting surfaces of the electrode 115 and the reflective layer 107 to d0=iλ/4n0 (i=1, 3, 5, . . . ), the luminance improves. Here, n0 is the effective refractive index of the layer from the light emitting position to the reflecting surface.

Furthermore, if the phase shift when light of a wavelength λ is reflected by the reflecting surface is accurately considered, an optical distance Lr from the light emitting position to the reflecting surface in the reflective layer 107 is expressed by the following equation (1), where yr[rad] is the phase shift when light of the wavelength λ is reflected by the reflecting surface of the reflective layer 107. Here, an optical distance L is a sum of the products each obtained from a refractive index nj of each layer of the organic functional layer 114 and a thickness dj of each layer. That is, L can be expressed as Σnj×dj, and can also be expressed as n0×d0. Here, φ is a negative value.

$$Lr = ( 2 m - ( φ r / π ) ) \times ( λ / 4 ) \qquad ( 1 )$$

In equation (1), m is an integer of 0 or more. Here, for φr=−π, Lr=λ/4 if m=0, and Lr=3λ/4 if m=1. These correspond to the configuration of the λ/4 interference condition with interference order i=1 and the configuration of the 3λ/4 interference condition with interference order i=3, respectively.

This also applies to the optical distance from the light emitting position of the light emitting layer in the organic functional layer 114 to the reflecting surface of the electrode 115. That is, if the phase shift when light of the wavelength λ is reflected by the reflecting surface in the electrode 115 is accurately considered, an optical distance Ls from the light emitting position to the reflecting surface in the electrode 115 is expressed by the following equation (2), where φs[rad] is the phase shift when light of the wavelength λ is reflected by the reflecting surface in the electrode 115.

$$Ls = ( 2 n - ( φ s / π ) ) \times ( λ / 4 ) \qquad ( 2 )$$

In equation (2), n is an integer of 0 or more. Here, for φs=−π, Ls=λ/4 if n=0, and Ls=3λ/4 if n=1. These correspond to the configuration of the λ/4 interference condition with interference order i=1 and the configuration of the 3λ/4 interference condition with interference order i=3, respectively.

Hence, from equations (1) and (2), the optical distance L between the reflecting surface in the reflective layer 107 and the reflecting surface in the electrode 115 is expressed by the following equation (3). Equation (3) is called the conditions for thin-film interference.

$$L = Lr + Ls = ( 2 ( m + n ) - ( 2 φ / π ) ) \times ( λ / 4 ) \qquad ( 3 )$$

In equation (3), φ is a sum of φr and φs. Here, a case where both m and n are 0 corresponds to the conditions for thin-film interference with the minimum order. Under this condition, L=λ/2 if φ=−2π.

At this time, for the actual light emitting device 100, when the view angle characteristic or the like which is in a trade-off relationship with the light extraction efficiency in the front direction is considered, it is not necessary to strictly satisfy equation (3). More specifically, the optical distance L may have an error within a range of ±λ/8 from the value that satisfies equation (3). Therefore, in the light emitting device 100 according to this embodiment, for example, it is only required to satisfy the following inequality (4).

$$( λ / 8 ) \times ( 4 ( m + n ) - ( 2 φ / π ) - 1 ) < L < ( λ / 8 ) \times ( 4 ( m + n ) - ( 2 φ / π ) + 1 ) \qquad ( 4 )$$

Furthermore, in inequality (4), m=0 and n=0 may be possible, as will be described later. Hence, it is only required to satisfy the following inequality (5).

$$( λ / 8 ) \times ( - ( 2 φ / π ) - 1 ) < L < ( λ / 8 ) \times ( - ( 2 φ / π ) + 1 ) \qquad ( 5 )$$

Here, the phase shift at the reflecting surface is approximately −π. Accordingly, letting φ=−2π here, inequality (5) can be transformed into the following inequality (6).

$$3 λ / 8 < L < 5 λ / 8 \qquad ( 6 )$$

Next, the pixel 201b that emits blue light in this embodiment will be described. The organic functional layer 114 includes a light emitting layer containing the light emitting dopant that emits blue light. If the PL peak wavelength of the light emitting dopant that emits blue light is 460 nm, λ in inequality (5) is 460 nm. According to inequality (5), the optical distance L suitable for the pixel 201b satisfies the following inequality (7). Here, for calculation, the sum of the phase shift upon reflection by the reflecting surface of the reflective layer 107 and the phase shift upon reflection by the reflecting surface of the electrode 115 is assumed to be φ=−1.37π.

$$99.5 nm < L < 214.6 nm \qquad ( 7 )$$

The reason for exemplifying the optical distance calculated with φ=−1.37π is that the phase shift amount upon reflection depends on the metal type and deposition process, and each of the phase shift φs and the phase shift φr takes a value of −0.5π or more and −π or less.

In an organic EL element, if the film thickness of the electrode 110 (for example, ITO) is 10 nm and the film thickness of the insulating layer 111 (for example, SiO) in the portion 152 is 3 nm, the optical distance of the organic functional layer 114 in inequality (7) satisfies the following inequality (8).

$$76.3 nm < L < 191.4 nm \qquad ( 8 )$$

Here, for calculation, it is assumed that the refractive index of the electrode 110 (ITO) for 460 nm is 1.9, and the refractive index of the insulating layer 111 (SiO) for 460 nm is 1.4.

The average refractive index of the organic functional layer 114 for 460 nm is often within a range of 1.8 or more and 2.1 or less. Therefore, a film thickness D in this embodiment satisfies the following inequality (9).

$$36.3 nm < D < 106.3 nm \qquad ( 9 )$$

Here, for the pixels 201r and 201g that emit light of colors other than blue in the light emitting device 100 as well, the insulating layer 111 can be appropriately set to satisfy inequality (5) in accordance with the color of light to be emitted. In a case where the pixels 201r and 201g emit red light and green light, respectively, and the PL peak wavelengths of the red and green light emitting dopants are 620 nm and 525 nm, respectively, the thicknesses r1 and g1 of the portions 152 of the insulating layers 111 may satisfy the following inequalities (10) and (11), respectively.

$$45.9 nm < r 1 < 74.5 nm \qquad ( 10 )$$

$$20.7 nm < g 1 < 32.3 nm \qquad ( 11 )$$

Here, it is assumed that the organic functional layer 114 is deposited integrally across the plurality of pixels 201, as shown in FIG. 2, and the optical distance L of the organic functional layer 114 satisfies inequality (8). For calculation, it is assumed that the electrode 110 (ITO) is deposited simultaneously across the plurality of pixels 201, the film thickness in the portion 151 is 10 nm, and the refractive index is 1.9. It is also assumed that the sum of the phase shift upon reflection by the reflecting surface of the reflective layer 107 and the phase shift upon reflection by the reflecting surface of the electrode 115 in the pixel 201r is φ=−1.53π, and the sum of the phase shift upon reflection by the reflecting surface of the reflective layer 107 and the phase shift upon reflection by the reflecting surface of the electrode 115 in the pixel 201g is φ=−1.45π.

The pixels 201 of the light emitting device 100 according to this embodiment are configured as described above. With this, it is possible to implement the light emitting device 100 that includes the optical resonance structure with improved light emission efficiency and display characteristic such as the field of view while suppressing the increase of power consumption.

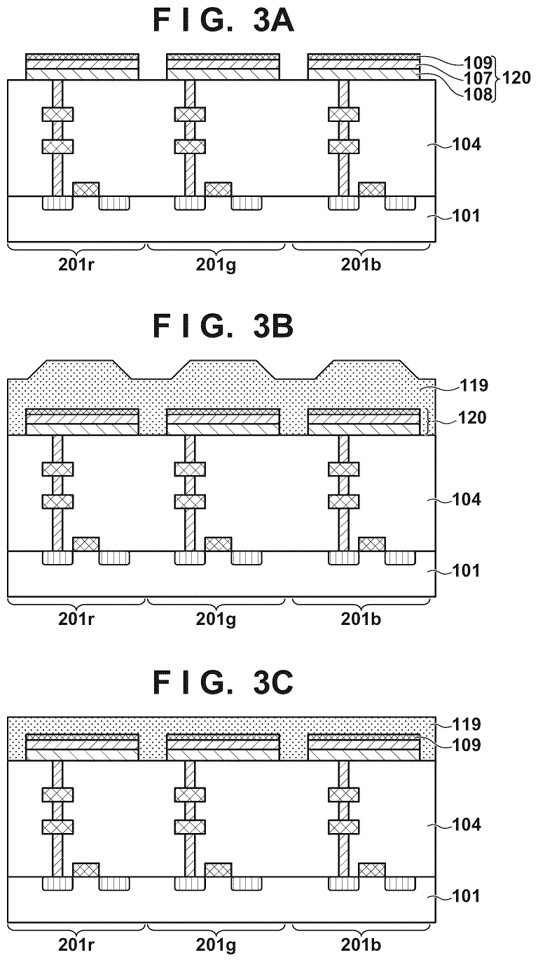

Next, an example of a manufacturing method of the light emitting device 100 shown in FIG. 2 will be described. Hereinafter, in the drawings showing the manufacturing method, some reference numerals are omitted to focus on the manufacturing method. However, they can be understood by referring to FIG. 2. First, as shown in FIG. 3A, transistors, the contact plugs 105, and the interlayer insulating layer 104 are formed on the substrate 101. Then, each of a Ti/TiN stacked structure to be the metal layer 108, AlCu to be the reflective layer 107, and TiN to be the metal layer 109 is formed using a sputtering method. By further performing a photolithography step and a dry etching step, the pixel electrode 120 is formed.

After the pixel electrode 120 is formed, as shown in FIG. 3B, a material film for forming the isolating insulating portion 119 is formed so as to cover the pixel electrode 120. For example, as the isolating insulating portion 119, SiO may be deposited using a plasma CVD method or a high-density plasma CVD method.

After the material film of the isolating insulating portion 119 is formed, as shown in FIG. 3C, the material film is planarized by a chemical mechanical polishing (CMP) process. At that time, by leaving the material film of the isolating insulating portion 119 on the metal layer 109, the metal layer 109 is not removed in the CMP process, and the flatness of the underlying layer improves. When planarizing the material film of the isolating insulating portion 119 by the CMP process, the planarization using the CMP process may be performed after providing an opening in a photoresist only on the metal layer 109 by using a photolithography step, and etching in advance the material film of the isolating insulating portion 119 exposed to the opening by using a dry etching step. This reduces the influence of the underlying steps generated due to the difference in underlying pattern density in the CMP process.

Then, as shown in FIG. 3D, the material film of the isolating insulating portion 119 is etched by an etch-back process, thereby exposing the metal layer 109. At that time, for example, a dry etching process with a high selectivity between the metal layer 109 and the material film of the isolating insulating portion 119 is used. To uniformly expose the metal layer 109 in the surface of the substrate 101, the material film of the isolating insulating portion 119 may be etched deeper than the upper surface of the metal layer 109. This can be adjusted by considering the unevenness of the underlying film caused by the etch-back process.

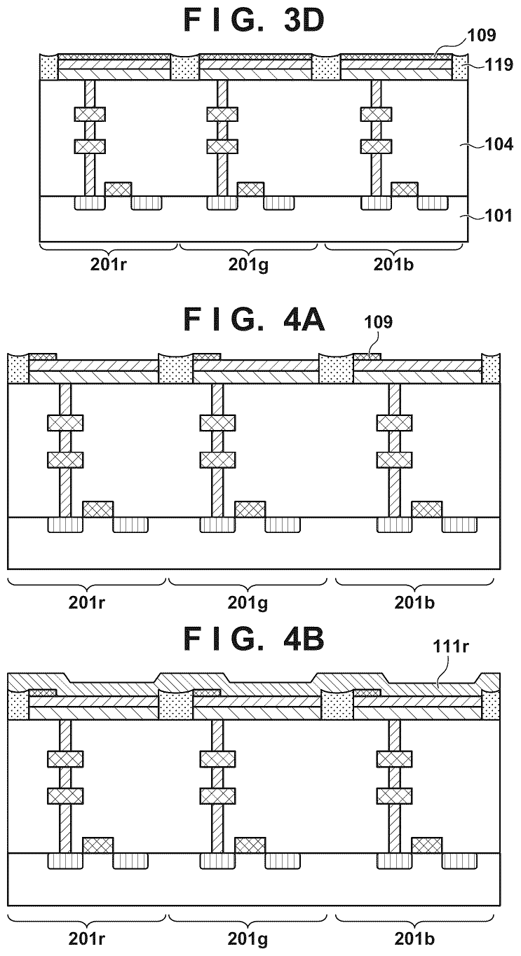

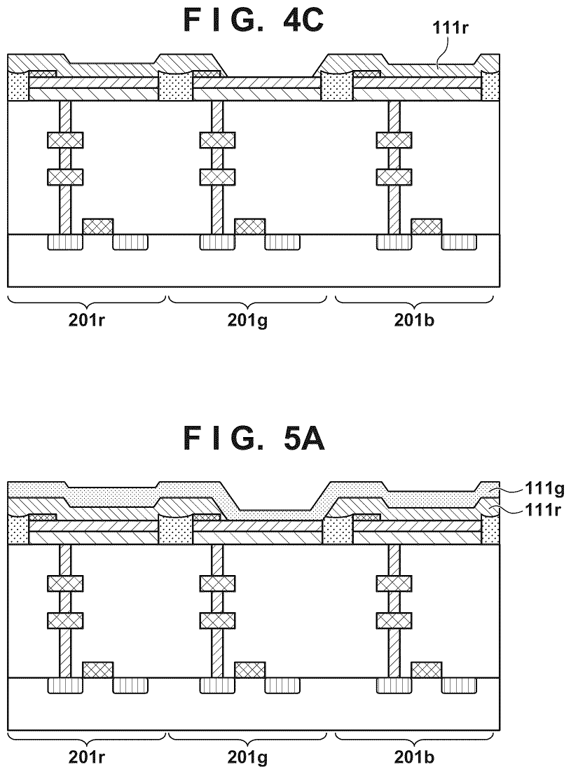

Next, as shown in FIG. 4A, a part of the metal layer 109 is etched using a photolithography step and a dry etching step, thereby exposing the reflective layer 107. For this dry etching step, an etching process with a high selectivity between the metal layer 109 and the reflective layer 107 can be used. For example, an isotropic dry etching process may be used.

After the metal layer 109 is formed, as shown in FIG. 4B, an insulating layer 111r is formed. Since the insulating layer 111r can significantly influence the light emission efficiency of the optical interference structure, SiO formed by a plasma CVD method or an ALD method may be used for the insulating layer 111r.

Then, as shown in FIG. 4C, the insulating layer 111r on the pixel 201g is etched using a photolithography step and a dry etching step so that the reflective layer 107 arranged in the pixel 201g is exposed. In this dry etching step, when the insulating layer 111r is formed of SiO and the reflective layer 107 is formed of AlCu, a high etching selectivity can be achieved due to the difference in film type. This can reduce the etching depth of the reflective layer 107 in the pixel 201g.

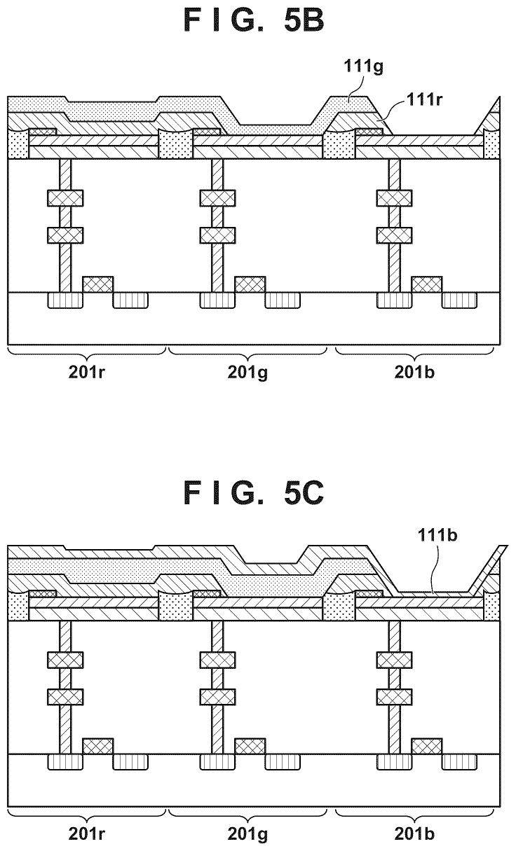

Then, as shown in FIG. 5A, an insulating layer 111g is formed. Since the insulating layer 111g can significantly influence the light emission efficiency of the optical interference structure, SiO formed by a plasma CVD method or an ALD method may be used for the insulating layer 111g.

After the insulating layer 111g is formed, as shown in FIG. 5B, the insulating layers 111r and 111g on the pixel 201b are etched using a photolithography step and a dry etching step so that the reflective layer 107 arranged in the pixel 201b is exposed. In this dry etching step, when the insulating layers 111r and 111g are formed of SiO and the reflective layer 107 is formed of AlCu, a high etching selectivity can be achieved due to the difference in film type. This can reduce the etching depth of the reflective layer 107 in the pixel 201b.

Then, as shown in FIG. 5C, an insulating layer 111b is formed. Since the insulating layer 111b can significantly influence the light emission efficiency of the optical interference structure, SiO formed by a plasma CVD method or an ALD method may be used for the insulating layer 111b.

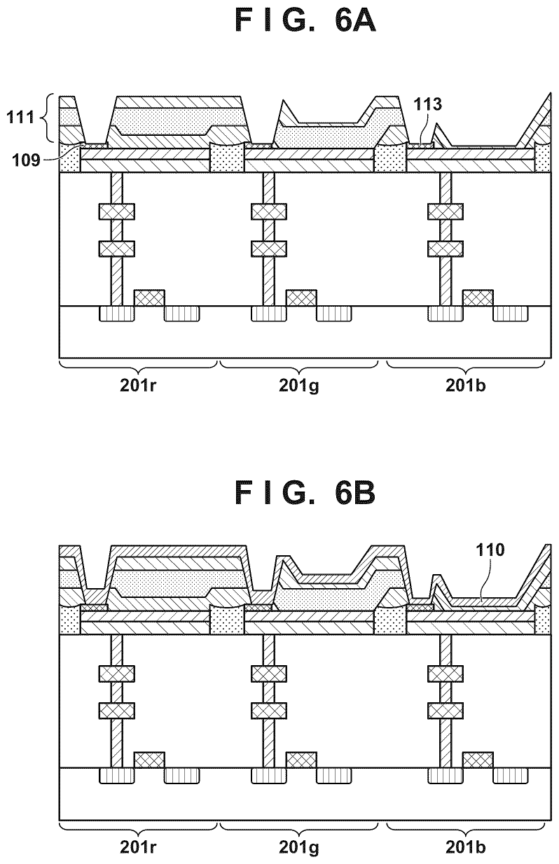

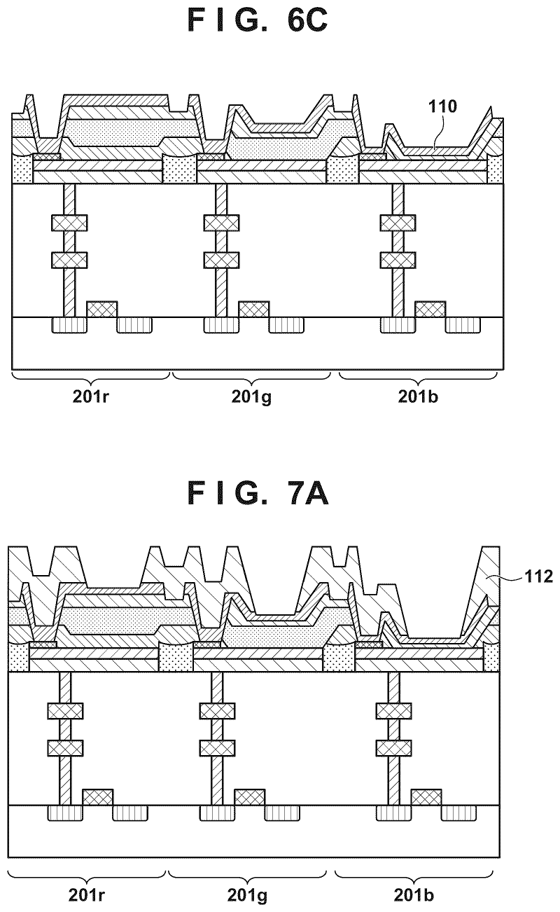

After the insulating layer 111b is formed, as shown in FIG. 6A, the insulating layer 111 (111r, 111g, and 111b) on the metal layer 109 is etched using a photolithography step and a dry etching step. Thus, openings (contact holes), each of which defines the contact region 113 where the metal layer 109 and the electrode 110 contact each other, are provided in the insulating layer 111.

Then, as shown in FIG. 6B, the material film of the electrode 110 is formed. As the electrode 110, ITO may be deposited using a sputtering method. When forming the electrode 110 by using the sputtering method, a process step may be adjusted so as to prevent the insulating layer 111 from being etched by etching components during the sputtering.

After the material film of the electrode 110 is formed, as shown in FIG. 6C, a predetermined region of the material film of the electrode 110 is etched and patterned using a photolithography step and a dry etching step. Thus, the electrode 110 is formed and isolated for each pixel 201.

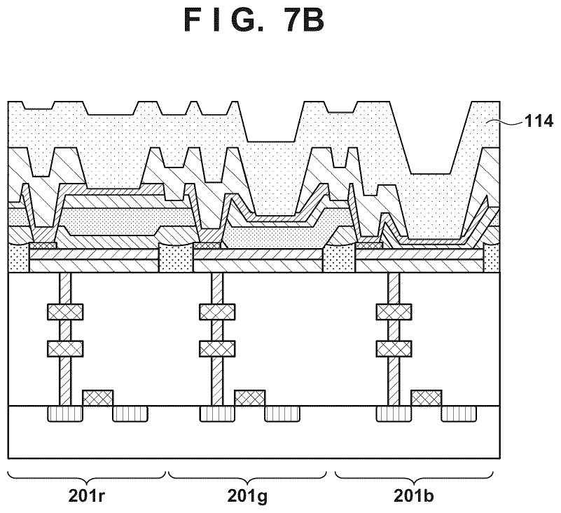

After the electrode 110 is formed, as shown in FIG. 7A, the material film of the bank 112 is formed on the electrode 110. As the material film of the bank 112, for example, an SiO film may be deposited using a plasma CVD method. Then, the bank 112 is formed by etching and patterning the material film of the bank 112 by using a photolithography step and a dry etching step so that an opening is provided in the light emitting region of each pixel 201. During etching for forming the bank 112, a part of the electrode 110 may be etched so that, as described above, the film thickness of the portion 151 of the electrode 110 becomes smaller than that of the adjacent portion.

After the bank 112 is formed, as shown in FIG. 7B, the organic functional layer 114 is formed. The organic functional layer 114 may be formed using, for example, a vapor deposition method using a vapor deposition mask.

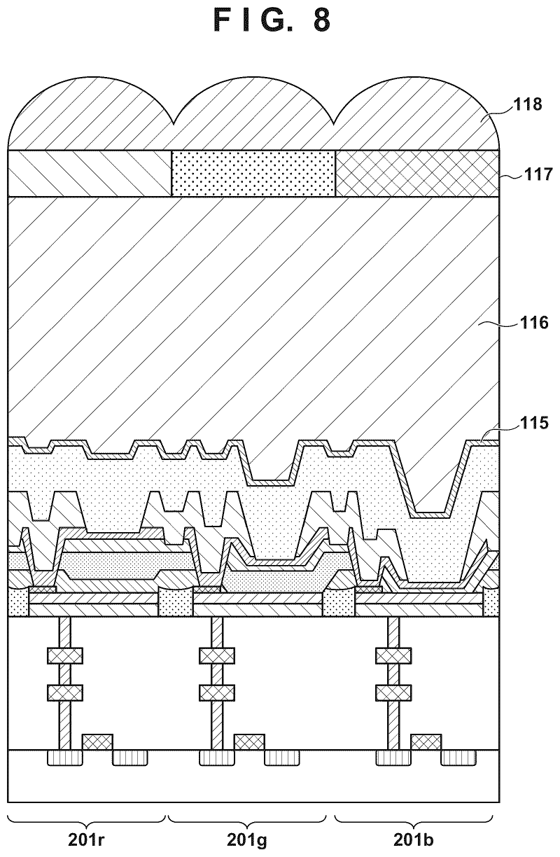

Then, as shown in FIG. 8, the electrode 115 is formed. The electrode 115 may be formed using a sputtering method. The electrode 115 may be a thin film of a transparent material. As described above, the electrode 115 may be a thin film of Au, Pt, Ag, Al, Cr, Mg, or an alloy of these. Furthermore, the sealing layer 116 is formed. The sealing layer 116 can have, for example, a stacked structure made of SiN, Al₂O₃, and the like deposited using a plasma CVD method, an ALD method, or the like. At that time, SiN may be deposited to a thickness of, for example, 2 μm or more. When the sealing layer 116 contains a thick layer of SiN, it is possible to prevent permeation of water in the atmosphere, and maintain the life and reliability of the organic functional layer 114. The color filter 117 is formed on the sealing layer 116 of each pixel 201 by using a photolithography method. Furthermore, as shown in FIG. 8, the microlens 118 may be formed on each pixel 201.

By using the steps described above, the light emitting device 100 shown in FIG. 2 may be manufactured. However, manufacturing of the light emitting device 100 is not limited to the above-described manufacturing method, and various methods can be used. The description has been provided above assuming that dry etching is used in the etching step. However, for example, wet etching or the like may be used. In the deposition step of each constituting member, an appropriate method may be used in accordance with the used material.

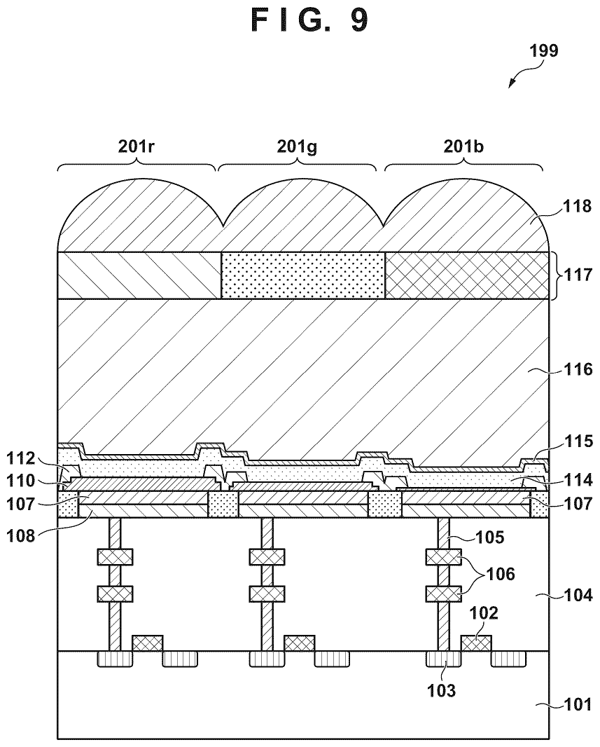

FIG. 9 is a sectional view of a light emitting device 199 of a comparative example. In the light emitting device 199, the reflective layer 107 and the electrode 110 are in direct contact with each other. In addition, the electrode 110 also functions as an optical adjustment layer. For example, using Al—Ni for the reflective layer 107 enables direct contact with the electrode 110 using ITO. Since Al—Ni and ITO have similar ionization tendencies, an electrolytic corrosion reaction and the like are less likely to occur in the process step after the direct contact. For Al—Ni, by adding a heat treatment step after the direct contact with ITO, a nickel alloy is precipitated and this can decrease the contact resistance with ITO. Then, the insulating layer 111 as the optical adjustment layer need not be provided. Therefore, for the optical resonance structure in which the interference order is reduced to improve the light emission efficiency and view angle characteristic, the light emitting device 199 is a strong candidate.

However, depending on the process condition for forming Al—Ni, the reflectance of Al—Ni is known to be, for example, 88% to 90% at a wavelength λ=450 nm in the visible light region. On the other hand, the reflectance of AlCu reaches 91% to 92%. For Al—Ni, the surface flatness of the reflective layer 107 is deteriorated due to the precipitates of the nickel alloy. Considering this difference in reflectance, compare the light emission efficiency of the pixel 201b under the interference condition expressed by equation (1) between the above-described light emitting device 100 and the light emitting device 199. This reveals that the light emitting device 100 exhibits a higher light emission efficiency than the light emitting device 199. This is because, since the light generated in the organic functional layer 114 undergoes multiple reflection between the reflective layer 107 and the electrode 115, the reflective layer 107 has a significant effect on the light emission efficiency per unit area of the pixel 201b.

As described above, in the light emitting device 100 according to this embodiment, the insulating layer 111 is arranged between the reflective layer 107 and the electrode 110 without making the reflective layer 107 and the electrode 110 directly contact each other. This enables selection of a material having a higher reflectance as the reflective layer 107. Furthermore, for example, ITO has a lower light transmittance in the visible light region than SiO. Therefore, as the optical adjustment layer, the insulating layer 111 using SiO is more likely to contribute to improving light emission efficiency than the electrode 110 using ITO. Arranging the insulating layer 111 between the reflective layer 107 and the electrode 110 allows for a wider range of materials to be selected for the reflective layer 107 and the optical adjustment layer, thereby enabling implementation of the light emitting device 100 with improved light emission efficiency.

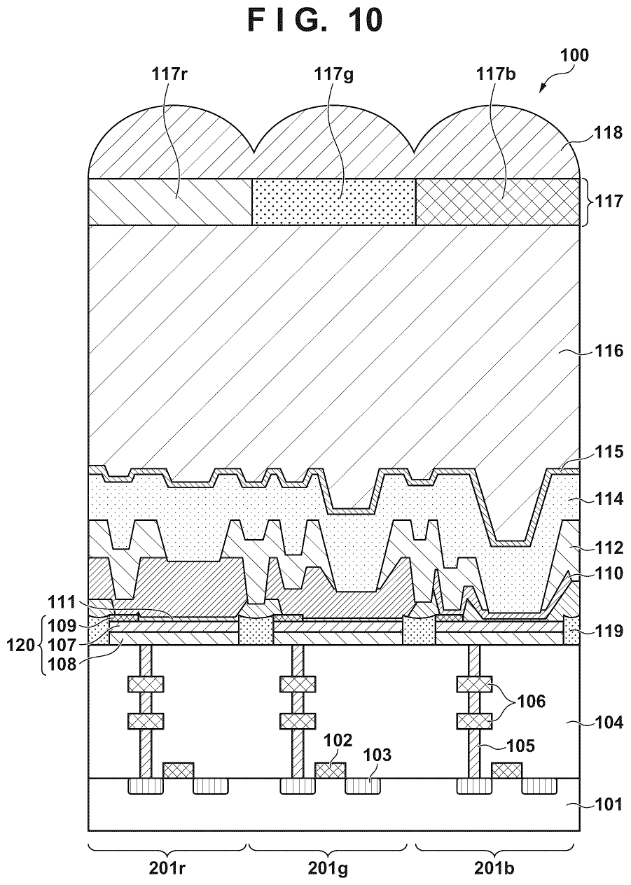

FIG. 10 is a sectional view showing a modification of the light emitting device 100 shown in FIG. 2. In the light emitting device 100 shown in FIG. 2, the film thickness of the insulating layer 111 is changed to adjust the optical distance between the reflective layer 107 and the electrode 115 for each of the pixels 201r, 201g, and 201b. On the other hand, in the configuration shown in FIG. 10, the film thickness of the electrode 110 is changed to adjust the optical distance between the reflective layer 107 and the electrode 115 for each of the pixels 201r, 201g, and 201b. In the configuration shown in FIG. 10, the film thickness of the electrode 110 can be formed thicker in the pixels 201r and 201g. This reduces the resistance of the electrode 110, thereby providing an effect contributing to reduction of power consumption of the light emitting device 100.

Similar to the configuration shown in FIG. 2, SiO or the like can be used for the insulating layer 111, and ITO or the like can be used for the electrode 110. ITO has a lower light transmittance in the visible light region than SiO. Accordingly, the light emission efficiency decreases in the pixels 201r and 201g as compared to the configuration shown in FIG. 2. However, formation of the insulating layer 111 is simplified as compared to the configuration shown in FIG. 2, and the cost of the manufacturing process can be suppressed.

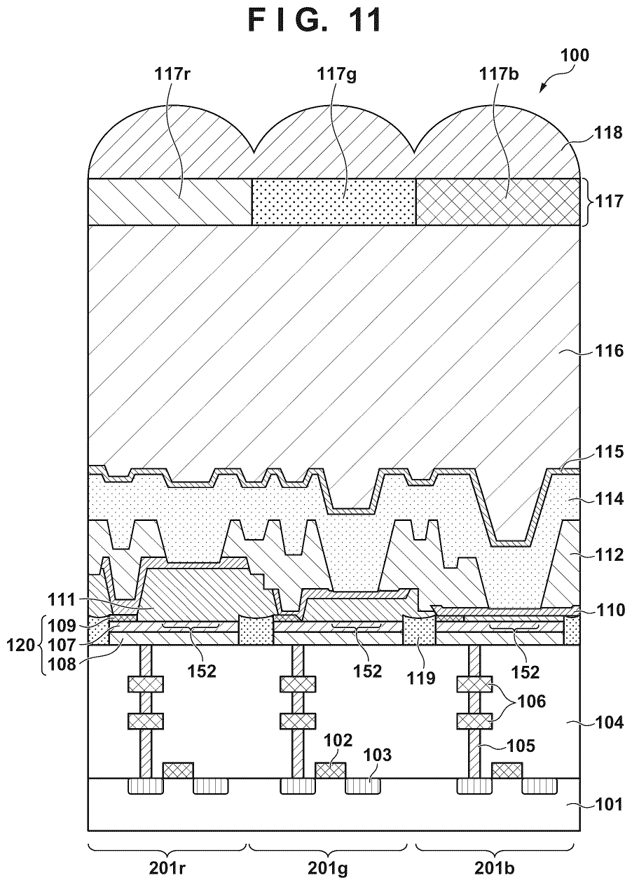

FIG. 11 is a sectional view showing a modification of the light emitting device 100 shown in FIG. 2. In the light emitting device 100 shown in FIG. 2, the reflective layer 107 is used as an etching stopper when etching the insulating layer 111, as shown in FIGS. 4C and 5B. Therefore, the outer edge of a portion of the insulating layer 111, which is continuous from the portion 152 and has the same film thickness as the portion 152, is located inside the outer edge of the reflective layer 107. On the other hand, in the configuration shown in FIG. 11, the outer edge of the portion of the insulating layer 111, which is continuous from the portion 152 and has the same film thickness as the portion 152, includes a portion located outside the outer edge of the reflective layer 107.

For example, SiO is used for the insulating layer 111 as in the configuration shown in FIG. 2. On the other hand, for example, a material such as SiN different from SiO is used for the upper surface of the isolating insulating portion 119. The isolating insulating portion 119 may have a single layer structure of SiN, or may have a stacked structure with the above-described materials such as SiO and SiOC. By changing the material of the insulating layer 111 and the material of the upper surface of the isolating insulating portion 119, it is possible to use the isolating insulating portion 119 as an etching stopper when etching the insulating layer 111 in the steps shown in FIGS. 4C and 5B.

By using the configuration shown in FIG. 11, it is unnecessary to perform patterning of the insulating layer 111 in the reflective layer 107. Accordingly, the contact area between the organic functional layer 114 and the electrode 110 in each pixel 201 can be increased. As a result, as compared to the configuration shown in FIG. 2, the ratio of the light emitting region (the region where the electrode 110 and the organic functional layer 114 are in contact with each other) to the reflective layer 107 can be increased. If the ratio is increased, for example, it is possible to reduce the size of the pixel 201 and increase the number of display pixels, thereby improving the view angle characteristic and the like and implementing the light emitting device 100 with higher resolution.

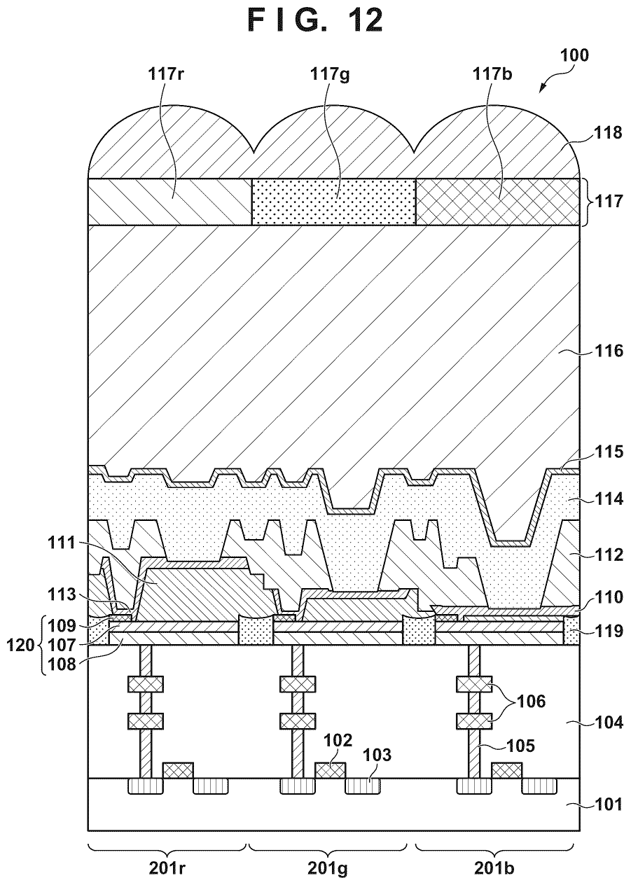

FIG. 12 is a sectional view showing a modification of the light emitting device 100 shown in FIG. 10. In each embodiment described above, the electrode 110 is not in contact with the reflective layer 107. As described above, this is because, when AlCu is used for the reflective layer 107 and ITO is used for the electrode 110, abnormal growth of the spike-like protrusions of the electrode 110 can occur. However, although a region of the reflective layer 107 that overlaps the light emitting region, where the electrode 110 and the organic functional layer 114 are in contact with each other, has a significant influence on the light emission efficiency of the optical interference structure, a region that does not overlap the light emitting region may have a small influence on the light emission efficiency of the optical interference structure. Therefore, in the configuration shown in FIG. 12, as the contact region 113, the electrode 110 is in contact not only with the metal layer 109 but also with the reflective layer 107 adjacent to the metal layer 109.

By using the configuration shown in FIG. 12, even if the size of the pixel 201 is reduced, the contact area between the electrode 110 and the pixel electrode 120 serving as an electrode pad can be ensured. That is, the increase of the contact resistance is suppressed. As a result, by using the configuration shown in FIG. 12, it is possible to implement the light emitting device 100 with higher resolution while suppressing the increase of power consumption.

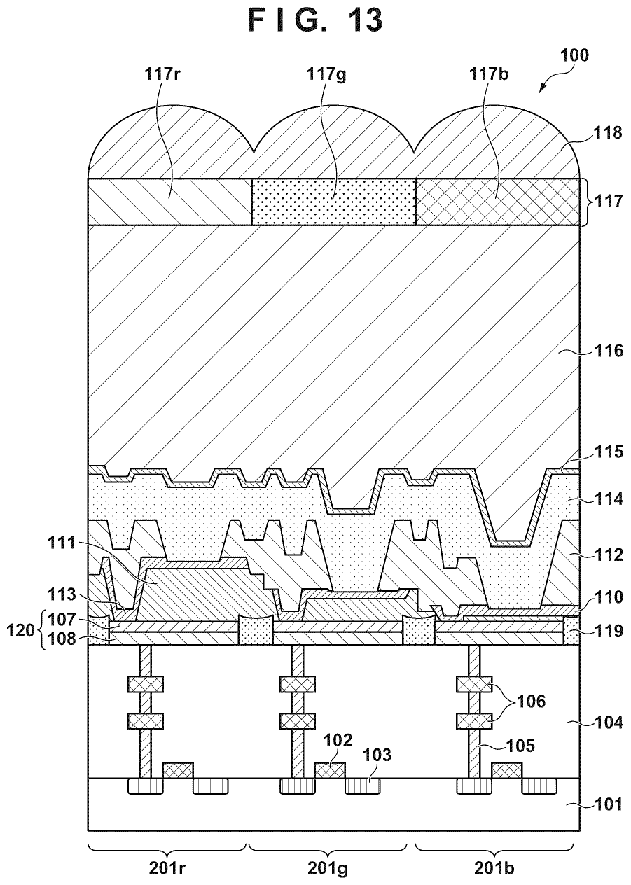

FIG. 13 is a sectional view showing a modification of the light emitting device 100 shown in FIG. 12. In the configuration shown in FIG. 13, the metal layer 109 is omitted, and the electrode 110 is in direct contact with the reflective layer 107 in the contact region 113. This eliminates the step with the reflective layer 107 in the outer edge of the metal layer 109. Accordingly, as described above, the increase of resistance of the electrode 110 and the step-cut thereof caused by the step can be suppressed.

In a case where the electrode 110 is directly bonded to the reflective layer 107 as in the configuration shown in FIG. 13, by selecting materials so as to decrease the difference in work function between the reflective layer 107 and the electrode 110, the increase of the contact resistance can be suppressed. Even if materials having a significant influence on the deposition process and electrolytic corrosion reaction, like AlCu and ITO, are selected, the contact region 113 is arranged in a region not overlapping the light emitting region. This can suppress the influence on the light emission efficiency of the optical interference structure, as described above.

The configuration of the contact region 113 shown in each of FIGS. 12 and 13 may be used, for example, in combination with the configuration shown in each of FIGS. 2 and 10. The embodiments described above can be used in appropriate combination.

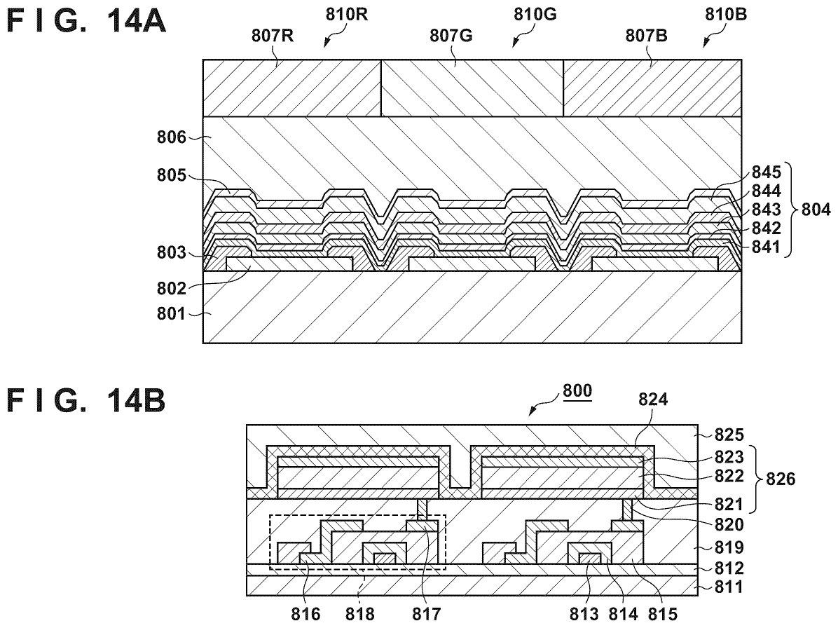

Application examples in which the light emitting device 100 according to this embodiment is applied to an image forming device, a display device, a photoelectric conversion device, an electronic apparatus, an illumination device, a moving body, a wearable device, and a head mounted display will now be described with reference to FIGS. 14A to 23B. The description will be given assuming that, for example, an organic light emitting element (OLED) such as an organic EL element using an organic light emitting material is arranged in the pixel 201 (to be sometimes referred to as the pixel or the sub-pixel hereinafter) arranged in the light emitting device 100. Details of each component arranged in the pixel 201 of the above-described light emitting device 100 will be described first, and the application examples will be described after that.

The organic light emitting element according to an embodiment of the present disclosure includes a first electrode, a second electrode, and an organic compound layer arranged between these electrodes. One of the first electrode and the second electrode is an anode, and the other is a cathode. In the organic light emitting element according to this embodiment, the organic compound layer may be either a single layer or a stacked body formed by a plurality of layers as long as it includes a light emitting layer. Here, if the organic compound layer is a stacked body formed from a plurality of layers, the organic compound layer may include a hole injection layer, a hole transport layer, an electron blocking layer, a hole/exciton blocking layer, an electron transport layer, an electron injection layer, and the like in addition to the light emitting layer. The light emitting layer may be a single layer or a stacked body formed from a plurality of layers. If the light emitting layer includes a plurality of layers, a charge generation layer may be arranged between the light emitting layers. The charge generation layer may be made of a compound having the LUMO lower than that of the hole transport layer, and the LUMO of the charge generation layer may be lower than the HOMO of the hole transport layer. Here, the molecular orbital energy of the organic compound layer may be the molecular orbital energy of the organic compound with the largest weight ratio in the organic compound layer.

The description is given here assuming that the closer the HOMO and LUMO are to the vacuum level, the “higher” they are. When the LUMO of the charge generation layer is lower than the HOMO of the hole transport layer, the LUMO of the charge generation layer is closer to the vacuum level than the HOMO of the hole transport layer.

The HOMO and LUMO in this specification can be calculated using molecular orbital calculation. The molecular orbital calculation is executed by a Density Functional Theory (DFT) or the like. B3LYP may be used as a functional, and 6-31G* as a basis function. Note that molecular orbital calculation can be executed using, for example, Gaussian 09 (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010.)

The HOMO and LUMO in this specification can be calculated using the ionization potential and band gap. The HOMO can be estimated by measuring the ionization potential. The ionization potential can be measured by dissolving the compound to be measured in a solvent such as toluene and using a measuring device such as AC-3. The band gap can be measured by dissolving the compound to be measured in a solvent such as toluene and irradiating it with excitation light. The band gap can be measured by measuring the excitation light absorption edge. Alternatively, the band gap can be measured by depositing the compound to be measured on a substrate such as glass, and exposing the deposited film to excitation light. The band gap can be measured by measuring the absorption edge of the absorption spectrum at which the deposited film absorbs excitation light.

The LUMO can be calculated using the band gap and ionization potential value. The LUMO can be estimated by subtracting the ionization potential value from the band gap.

The LUMO can also be estimated from the reduction potential. For example, the one-electron reduction potential is estimated using cyclic voltammetry (CV) measurement. The CV measurement can be performed, for example, in a DMF solution of 0.1 M tetrabutylammonium perchlorate using a reference electrode of Ag/Ag⁺, a counter electrode of Pt, and a working electrode of glassy carbon. The LUMO can be estimated by adding −4.8 eV to the difference between the reduction potential of the obtained compound and that of ferrocene.

If the organic compound according to this embodiment is contained in the light emitting layer, the light emitting layer may be a layer made of only the organic compound according to this embodiment or a layer made of the organic metal complex according to this embodiment and another compound. Here, if the light emitting layer is a layer made of the organic metal complex according to this embodiment and another compound, the organic compound according to this embodiment may be used as a host or a guest of the light emitting layer. Alternatively, the organic compound may be used as an assist material that can be contained in the light emitting layer. Here, the host is a compound whose mass ratio is largest in the compounds forming the light emitting layer. The guest is a compound whose mass ratio is smaller than that of the host in the compounds forming the light emitting layer, and is a compound responsible for main light emission. The assist material is a compound whose mass ratio is smaller than that of the host in the compounds forming the light emitting layer, and which assists light emission of the guest. Note that the assist material is also called a second host. The host material can be called a first compound, and the assist material a second compound.

If the organic compound according to an embodiment is used as the guest of the light emitting layer, the concentration of the guest may be 0.01 mass % (inclusive) to 20 mass % (inclusive) relative to the entire light emitting layer, or may be 0.1 mass % (inclusive) to 10 mass % (inclusive). The guest is also called a dopant.

The organic metal complex according to this embodiment can be used as the constituent material of the organic compound layer other than the light emitting layer forming the organic light emitting element according to this embodiment. More specifically, the organic metal complex may be used as the constituent material of an electron transport layer, an electron injection layer, a hole transport layer, a hole injection layer, a hole blocking layer, or the like. In this case, the light emission color of the organic light emitting element is not limited to red. More specifically, it may be white or an intermediate color.

A conventionally known low molecular weight and high molecular weight hole injection compound or hole transport compound, a compound serving as a host, a light emitting compound, an electron injection compound or electron transport compound, or the like can be used together as needed. Examples of these compounds will be described below.

As a hole injection/transport material, a material that has a high hole mobility such that hole injection from the anode is facilitated, and injected holes can be transported to the light emitting layer can suitably be used. Also, a material having a high glass transition point temperature can suitably be used to reduce degradation of film quality such as crystallization in the organic light emitting element. Examples of low molecular weight and high molecular weight materials having hole injection/transport performance are a triarylamine derivative, an arylcarbazole derivative, a phenylenediamine derivative, a stilbene derivative, a phthalocyanine derivative, a porphyrin derivative, a poly(vinyl carbazole), a poly(thiophene), and other conductive polymers. The above-described hole injection/transport material can suitably be used for the electron blocking layer as well. Detailed examples of compounds used as the hole injection/transport material will be shown below. The material is not limited to these.

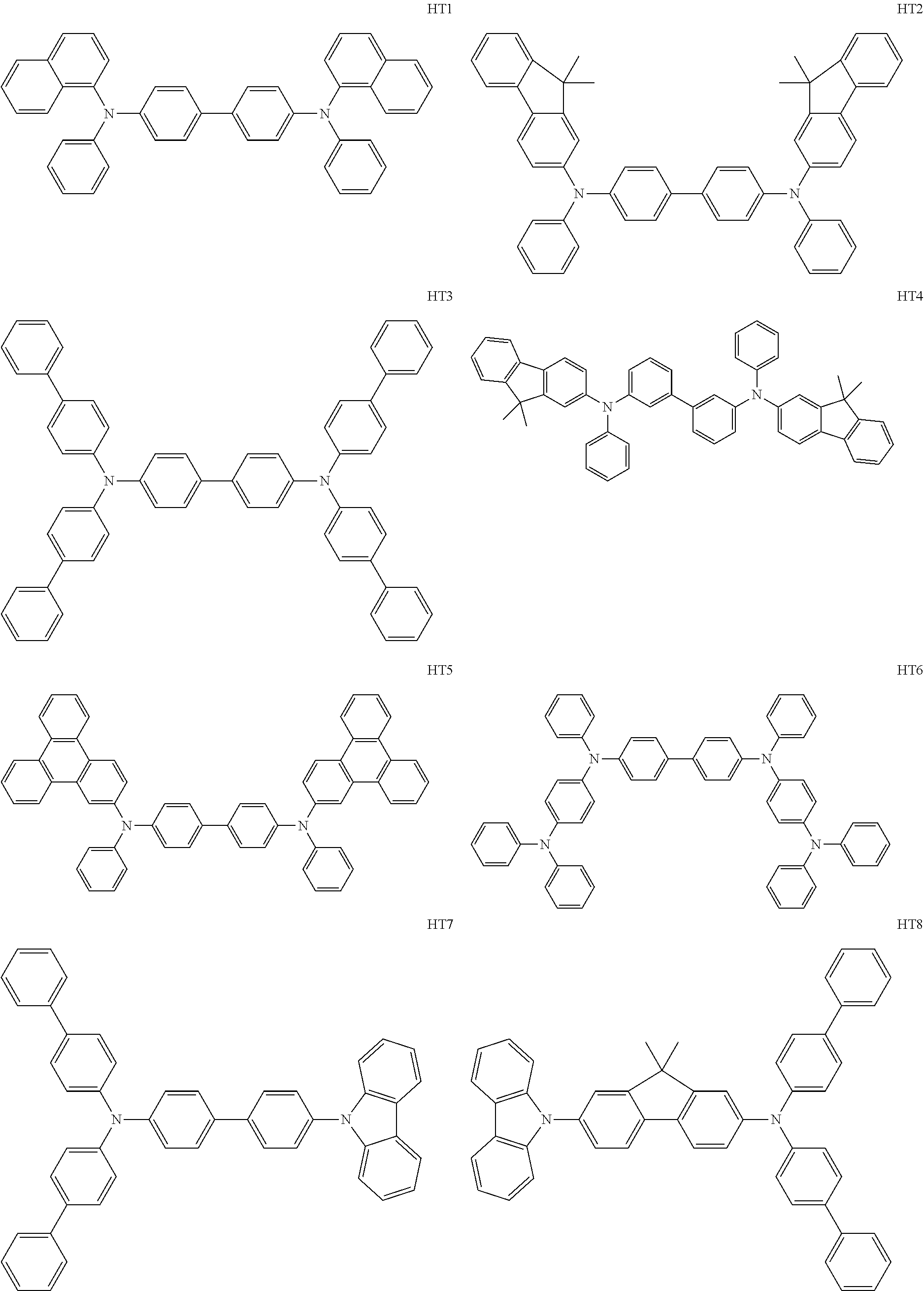

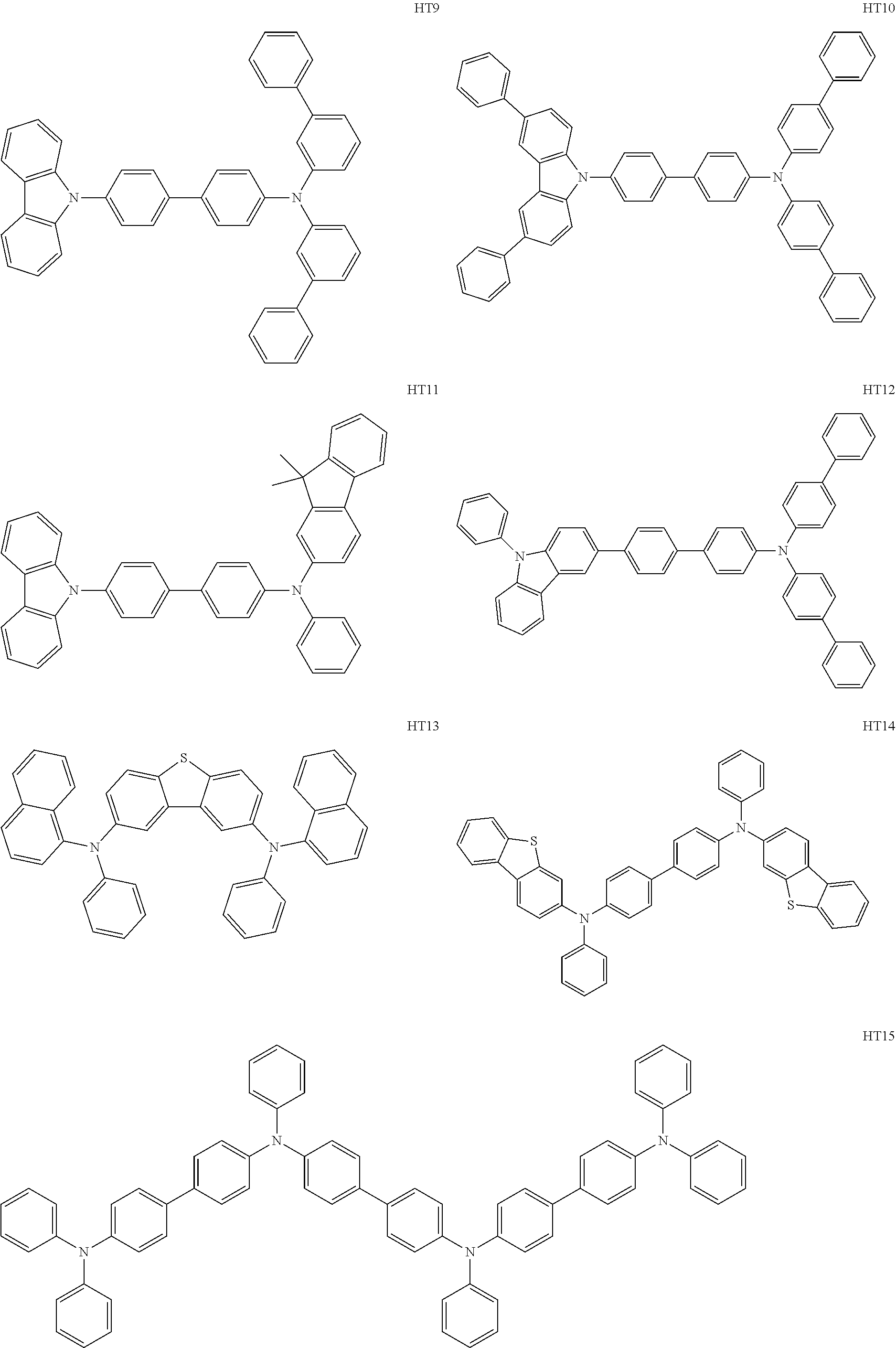

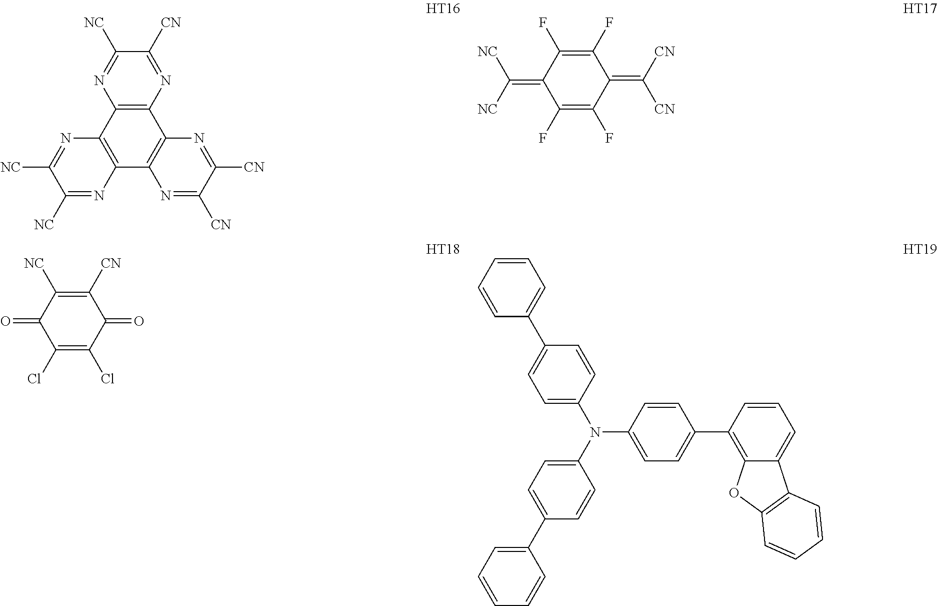

In the hole transport materials, HT16 to HT18 can decrease the driving voltage when used in a layer in contact with the anode. HT16 is widely used in an organic light emitting element. HT2, HT3, HT4, HT5, HT6, HT10, and HT12 can be used in an organic compound layer adjacent to HT16. A plurality of materials may be used in one organic compound layer.

Examples of the light emitting material mainly concerning the light emitting function are condensed-ring compounds (for example, a fluorene derivative, a naphthalene derivative, a pyrene derivative, a perylene derivative, a tetracene derivative, an anthracene derivative, and rubrene), a quinacridone derivative, a coumarin derivative, a stilbene derivative, an organic aluminum complex such as tris(8-quinolinolato)aluminum, an iridium complex, a platinum complex, a rhenium complex, a copper complex, a europium complex, a ruthenium complex, and polymer derivatives such as a poly(phenylenevinylene) derivative, a poly(fluorene) derivative, and a poly(phenylene) derivative.

Detailed examples of compounds used as the light emitting material will be shown below. The material is not limited to these.

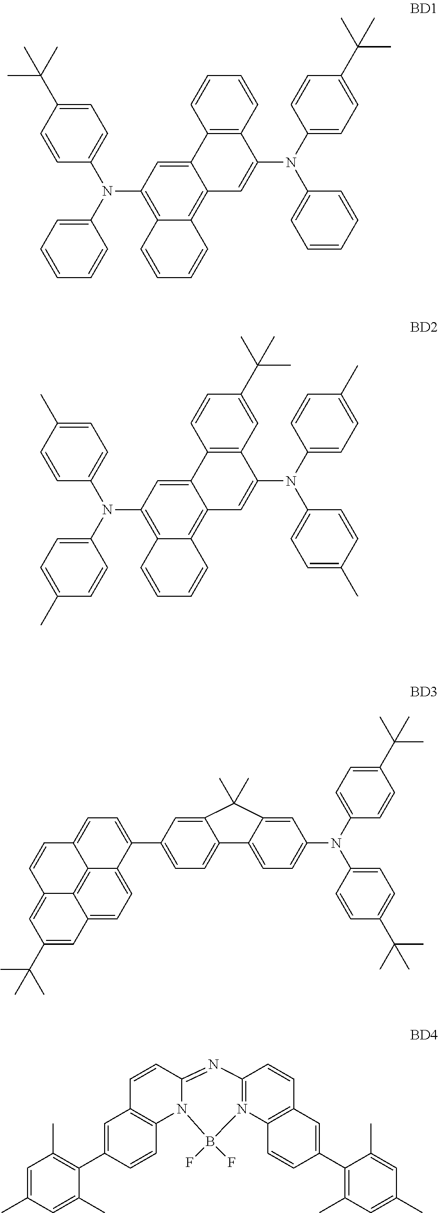

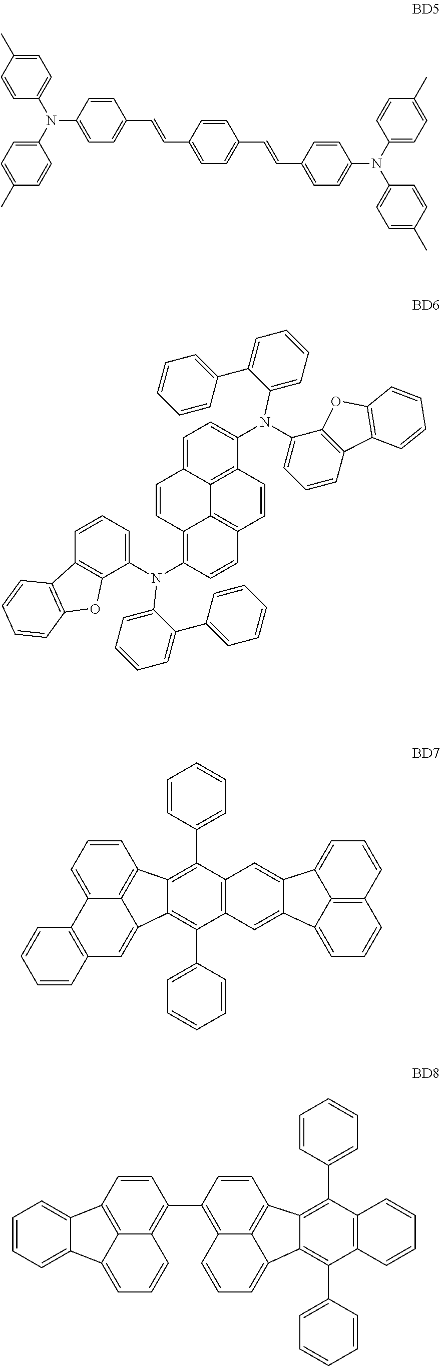

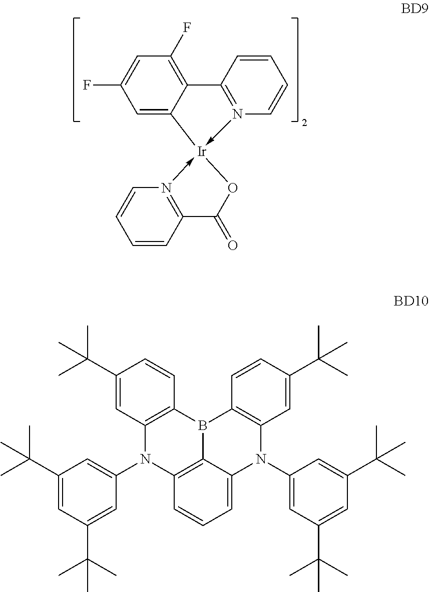

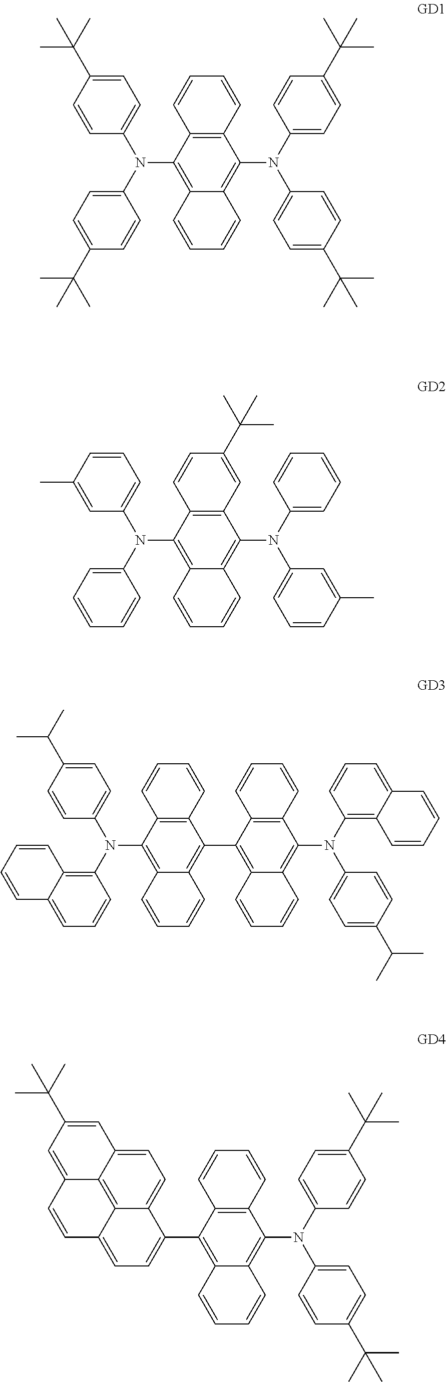

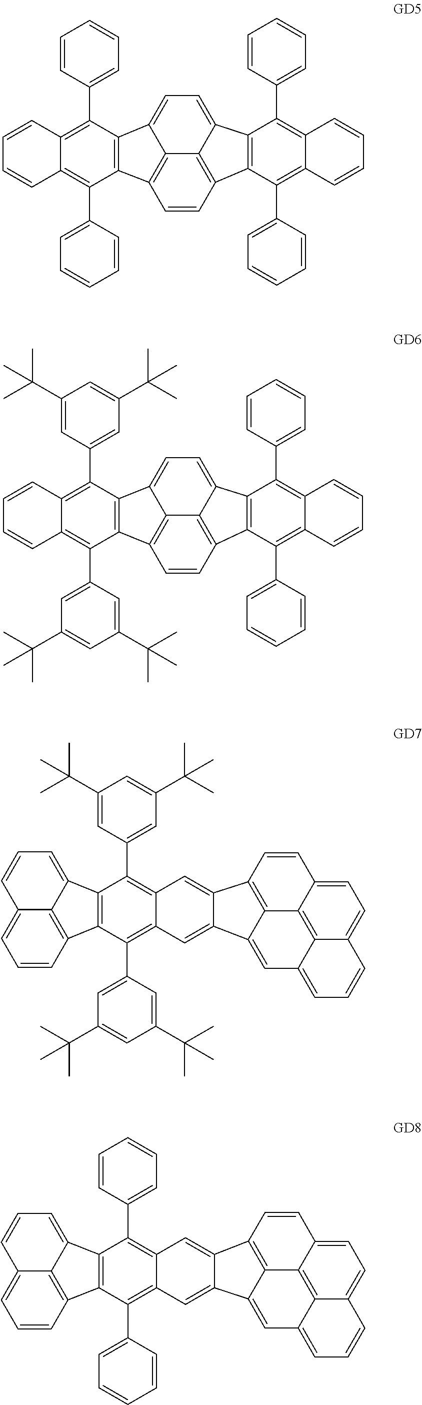

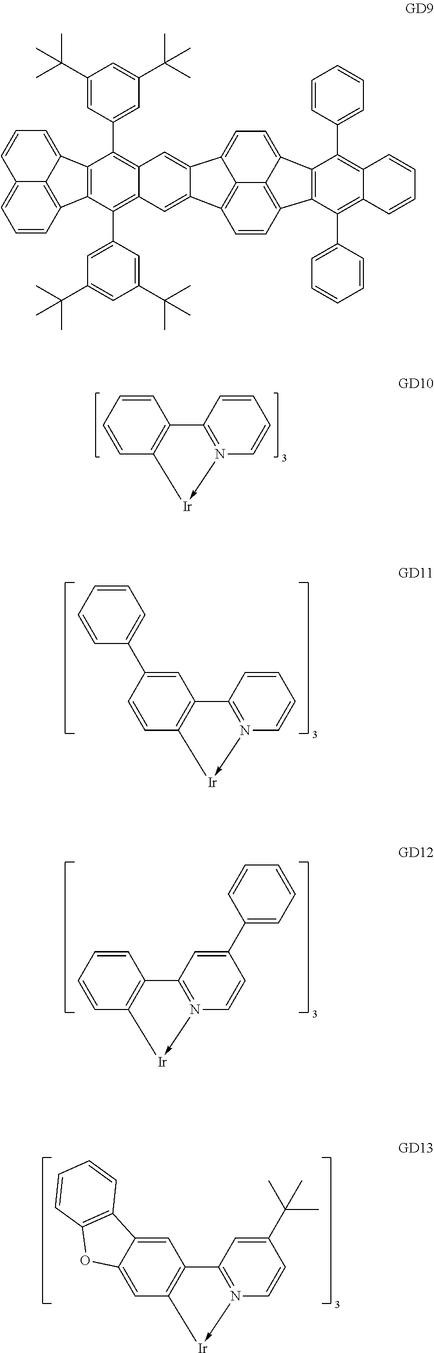

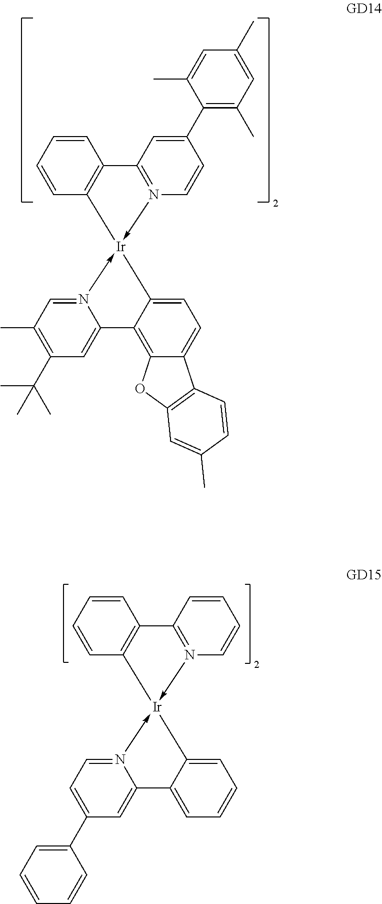

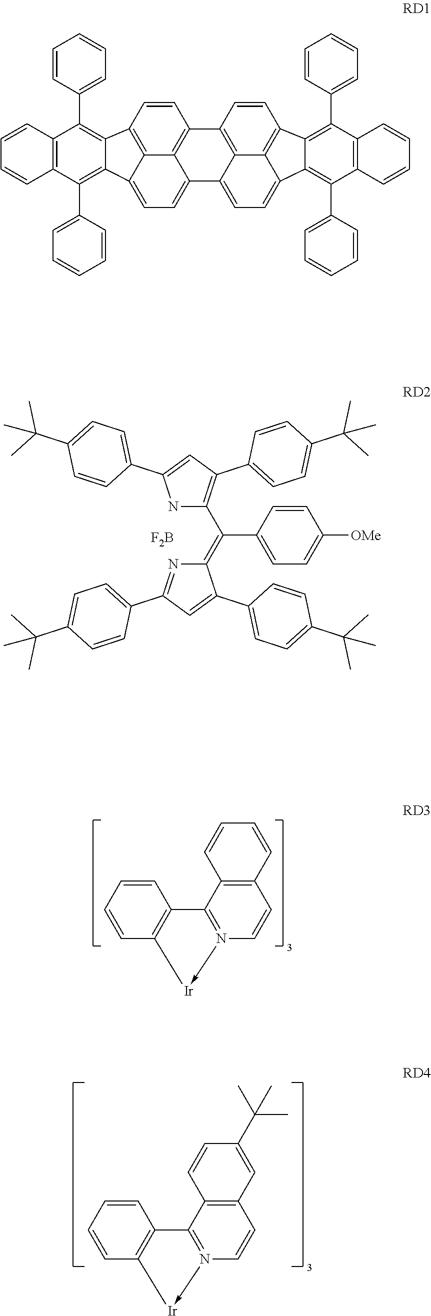

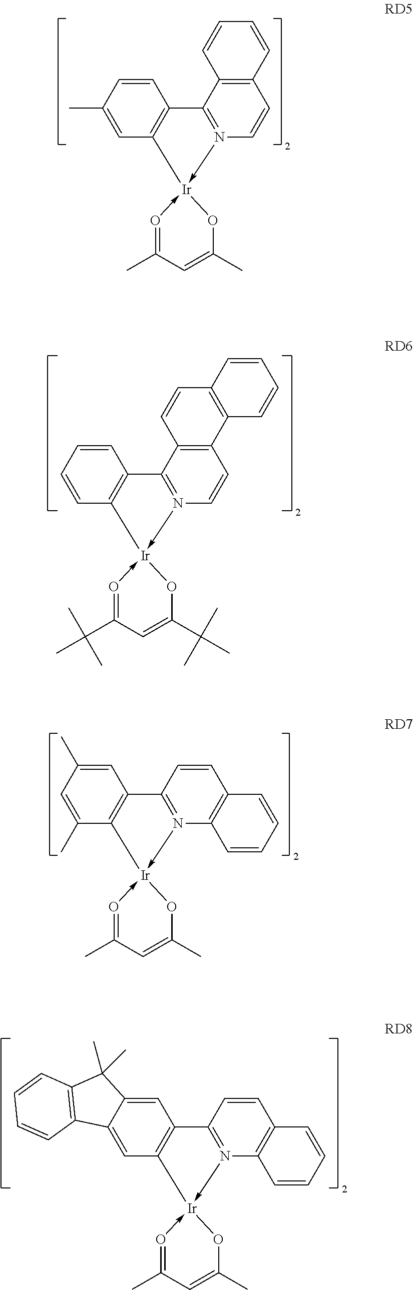

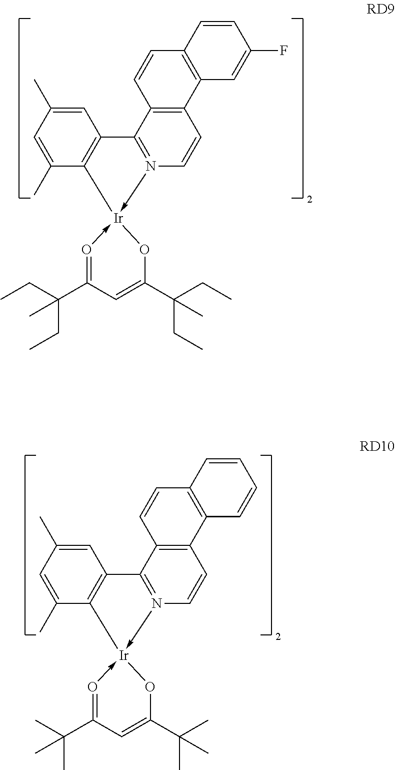

If the light emitting material is a hydrocarbon compound, this is suitable because it is possible to reduce lowering of light emission efficiency caused by exciplex formation or lowering of color purity due to a change of the light emission spectrum of the light emitting material caused by exciplex formation.

The hydrocarbon compound is a compound made of only carbon and hydrogen, and includes BD7, BD8, GD5 to GD9, and RD1 in the compounds exemplified above.

If the light emitting material is a condensed polycyclic compound including a 5-membered ring, this is suitable because oxidation hardly occurs because of a high ionization potential, and a long-life element with high durability can be obtained. This includes BD7, BD8, GD5 to GD9, and RD1 in the compounds exemplified above.

Examples of the light emitting layer host or the light emission assist material contained in the light emitting layer are an aromatic hydrocarbon compound or its derivative, a carbazole derivative, a dibenzofuran derivative, a dibenzothiophene derivative, an organic aluminum complex such as tris(8-quinolinolato)aluminum, and an organic beryllium complex.

Detailed examples of compounds used as the light emitting layer host or the light emission assist material contained in the light emitting layer will be shown below. The material is not limited to these.

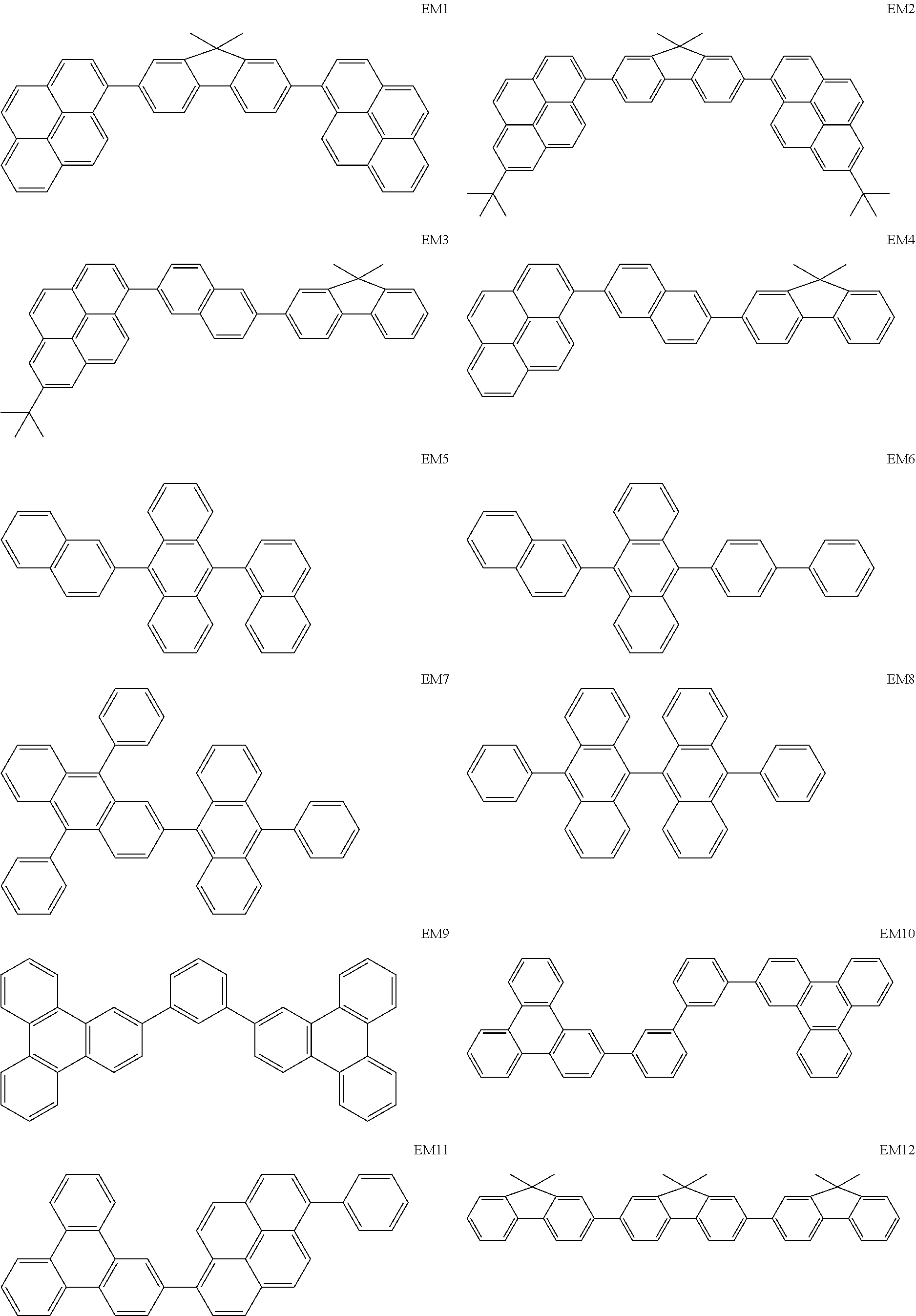

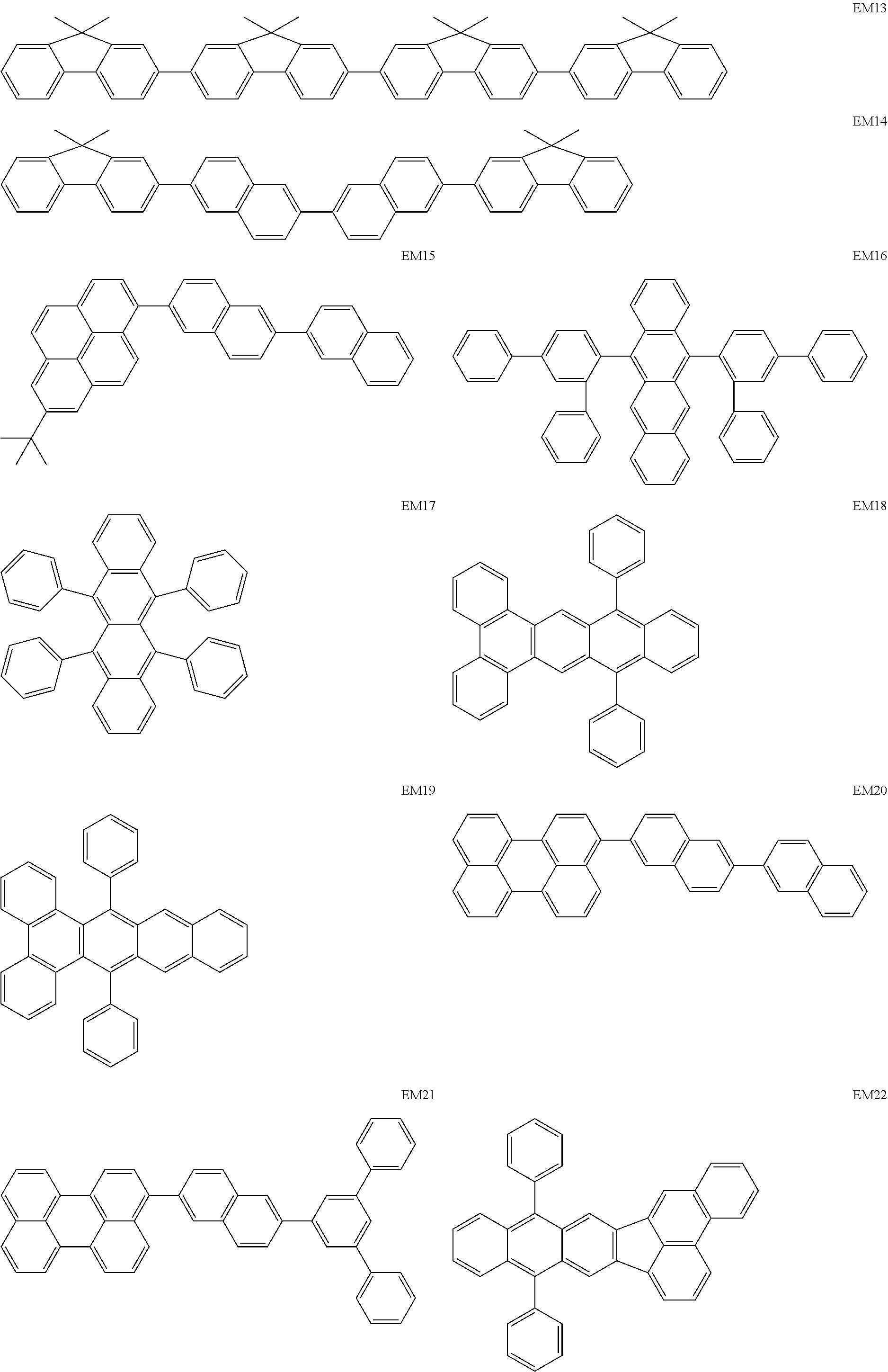

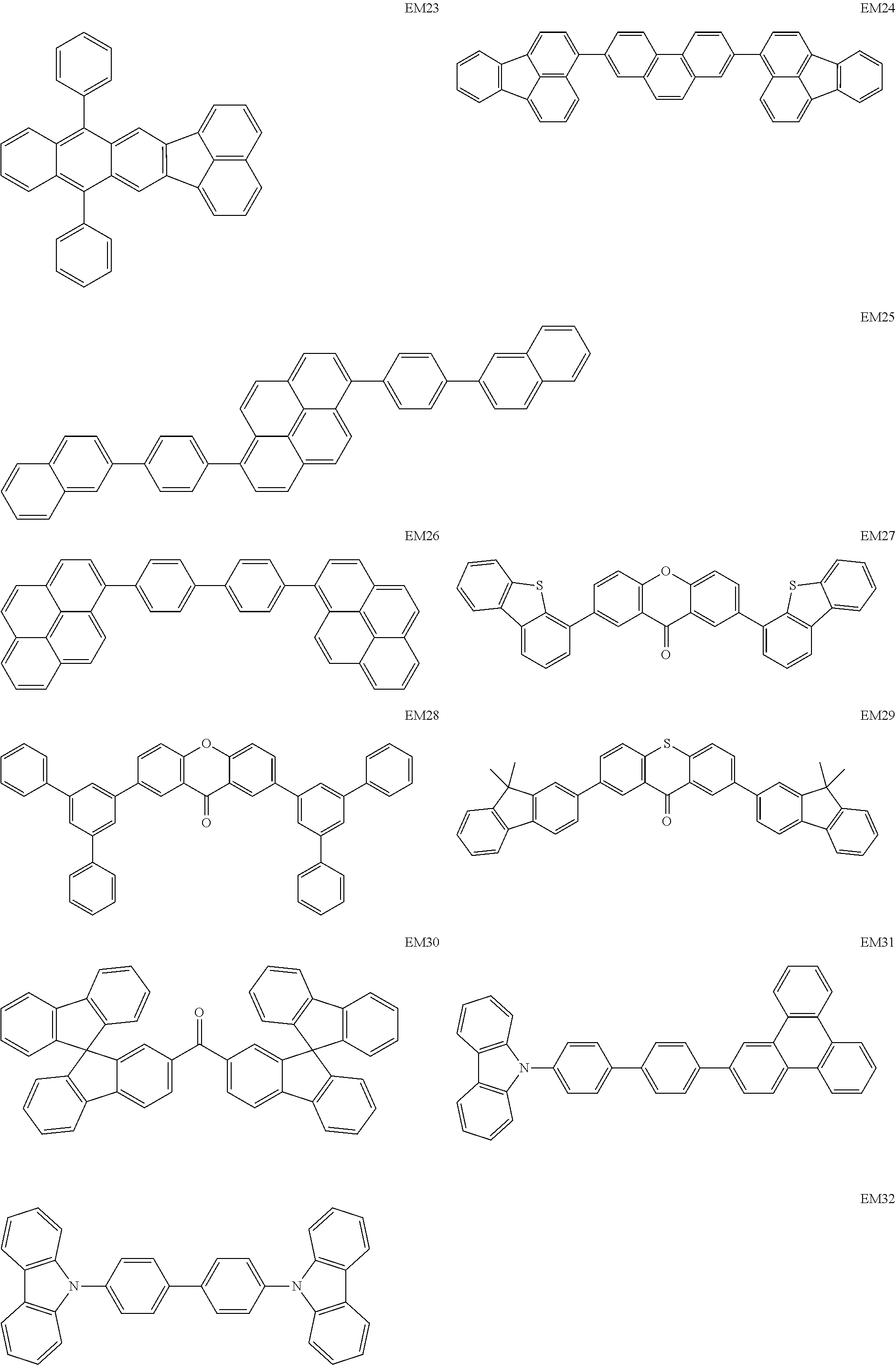

The host material may be a hydrocarbon compound. The hydrocarbon compound is a compound made of only carbon and hydrogen, and includes EM1 to EM12 and EM16 to EM27 in the compounds exemplified above. As the host material, a material that has, in a single bond that bonds an aryl group unit in its structure, no carbon-heteroatom bonds, like F3 in compound 1, is suitable from the viewpoint of stability.

The electron transport material can arbitrarily be selected from materials capable of transporting electrons injected from the cathode to the light emitting layer, and is selected in consideration of balance to the hole mobility of the hole transport material. Examples of the material having electron transport performance are an oxadiazole derivative, an oxazole derivative, a pyrazine derivative, a triazole derivative, a triazine derivative, a quinoline derivative, a quinoxaline derivative, a phenanthroline derivative, an organic aluminum complex, and condensed-ring compounds (for example, a fluorene derivative, a naphthalene derivative, a chrysene derivative, and an anthracene derivative). The above-described electron transport material can also be used for the hole blocking layer as well.

Detailed examples of compounds used as the electron transport material will be shown below. The material is not limited to these.

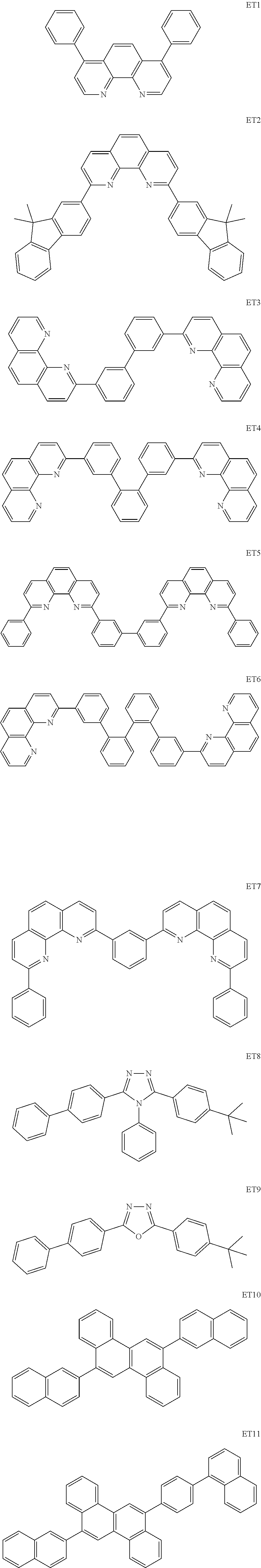

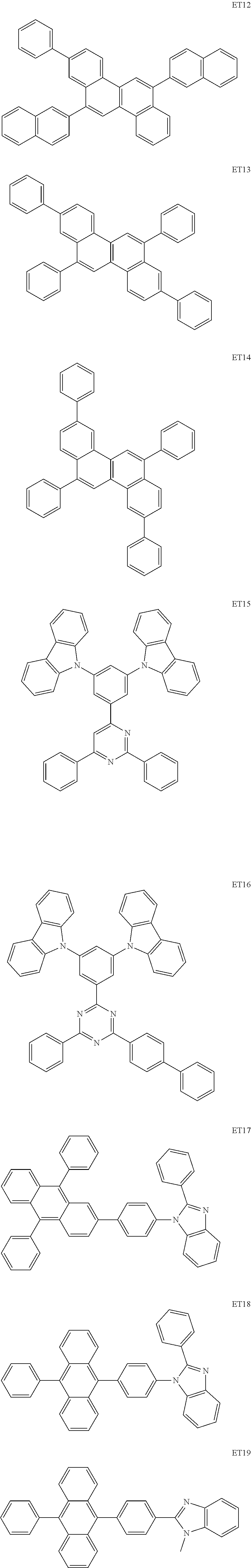

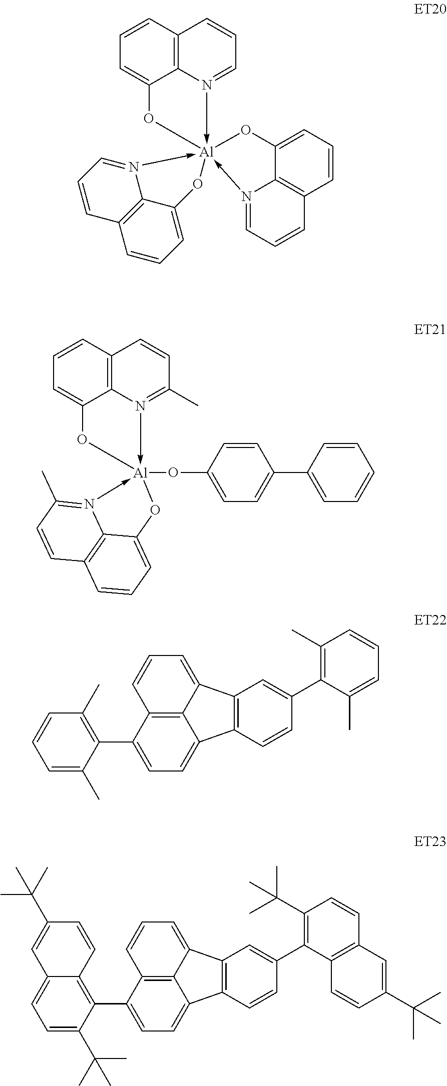

The electron injection material can arbitrarily be selected from materials capable of facilitating electron injection from the cathode, and is selected in consideration of balance to hole injection. The organic compound includes an n-type dopant and a reducible dopant. Examples are a compound containing an alkali metal such as lithium fluoride, a lithium complex such as a lithium-quinolinol complex, a benzo-imidazolidene derivative, an imidazolidene derivative, a fulvalene derivative, and an acridine derivative.

The electron injection material can also be used together with the above-described electron transport material.

### Configuration of Organic Light Emitting Element

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case where a planarizing layer is provided between the color filter and the microlens.

### Substrate

Quartz, glass, a silicon wafer, a resin, a metal, or the like may be used as a substrate. Furthermore, a switching element such as a transistor, a wiring pattern, and the like may be provided on the substrate, and an insulating layer may be provided thereon. The insulating layer may be made of any material as long as a contact hole can be formed so that the wiring pattern can be formed between the first electrode and the substrate and insulation from the unconnected wiring pattern can be ensured. For example, a resin such as polyimide, silicon oxide, silicon nitride, or the like may be used for the insulating layer.

### Electrode

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

If the electrode is used as a reflective electrode, for example, chromium, aluminum, silver, titanium, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the present disclosure is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be atop emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

### Pixel Isolation Layer

A pixel isolation layer may be formed by a so-called silicon oxide, such as silicon nitride (SiN), silicon oxynitride (SiON), or silicon oxide (SiO), formed using a Chemical Vapor Deposition (CVD) method. To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, the taper angle of the side wall of the pixel isolation layer or the film thickness of the pixel isolation layer can be adjusted to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by generation of a dark spot or occurrence of a conductive failure of the second electrode can be reduced.

According to this embodiment, even if the taper angle of the side wall of the pixel isolation layer is not steep, it is possible to effectively suppress leakage of charge to an adjacent pixel. As a result of this consideration, it has been found that the taper angle of 60° (inclusive) to 90° (inclusive) can sufficiently reduce the leakage of charge. The film thickness of the pixel isolation layer may be 10 nm (inclusive) to 150 nm (inclusive). A similar effect can be obtained in a configuration including only pixel electrodes without the pixel isolation layer. However, in this case, the film thickness of the pixel electrode is set to be equal to or smaller than half the film thickness of the organic layer or the end portion of the pixel electrode is formed to have a forward tapered shape of less than 60°. With this, short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes. If a plurality of light emitting layers are provided, a charge generation portion may be arranged between the first light emitting layer and the second light emitting layer. The charge generation portion may contain an organic compound with a lowest unoccupied molecular orbital energy (LUMO) of −5.0 eV or less. The same applies to a case where a charge generation portion is provided between the second light emitting layer and the third light emitting layer.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular weight material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting device may include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this configuration, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programming circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a PenTile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

### Application of Organic Light Emitting Element of Embodiment of Present Disclosure

The organic light emitting element according to an embodiment of the present disclosure can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

More details will be described next with reference to the accompanying drawings. FIG. 14A shows an example of a pixel arranged in the light emitting device 100. The pixel includes sub-pixels 810. The sub-pixels are divided into sub-pixels 810R, 810G, and 810B by light emission colors. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can be electrically connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include a plurality of layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

A light emitting device 800 shown in FIG. 14B is provided with an organic light emitting element 826 as an example of a light emitting element and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 14B. That is, one of the anode and cathode and one of the source electrode and drain electrode of the TFT are electrically connected. The TFT indicates a thin-film transistor.

In the light emitting device 800 shown in FIG. 14B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the light emitting device 800 shown in FIG. 14B, but another switching element may be used instead.

The transistor used in the light emitting device 800 shown in FIG. 14B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the light emitting device 800 shown in FIG. 14B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Here, the switching element according to this embodiment is not limited to the TFT, and may be a transistor formed from low-temperature polysilicon or an active matrix driver formed on the substrate such as a silicon substrate. The term “on the substrate” may mean “in the substrate”. Whether to provide a transistor in the substrate or use a TFT is selected based on the size of the display unit. For example, if the size is about 0.5 inch, the organic light emitting element may be provided on the silicon substrate.

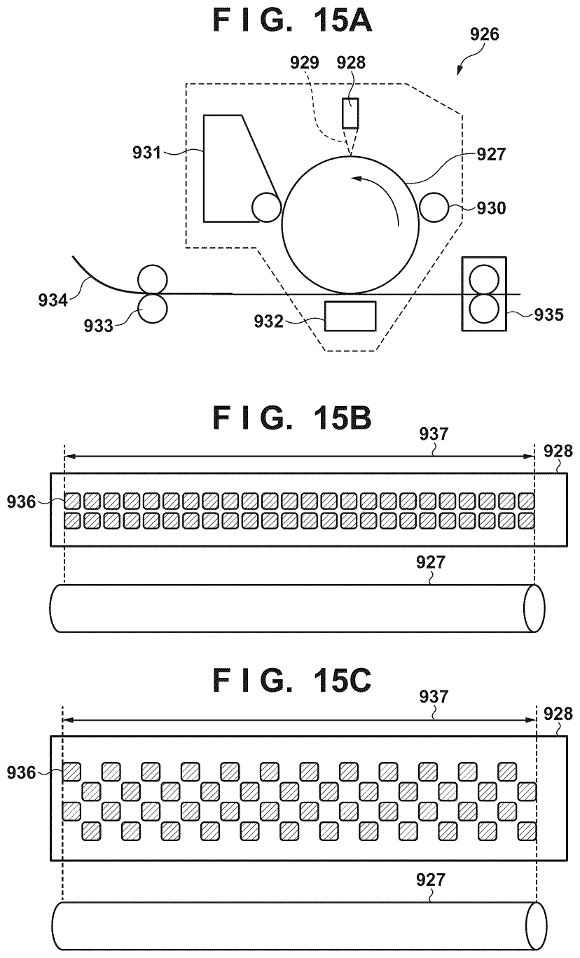

FIGS. 15A to 15C are schematic views showing an example of an image forming device using the light emitting device 100 according to this embodiment. An image forming device 926 shown in FIG. 15A includes a photosensitive member 927, an exposure light source 928, a developing unit 931, a charging unit 930, a transfer device 932, a conveyance unit 933 (a conveyance roller in the configuration shown in FIG. 15A), and a fixing device 935.

Light 929 is emitted from the exposure light source 928, and an electrostatic latent image is formed on the surface of the photosensitive member 927. The light emitting device 100 can be applied to the exposure light source 928. The developing unit 931 can function as a developing device that includes a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 can be, for example, paper, a film, or the like. The fixing device 935 fixes the image formed on the print medium.

Each of FIGS. 15B and 15C is a schematic view showing a form in which a plurality of light emitting units 936 are arranged in the exposure light source 928 along the longitudinal direction of a long substrate. The light emitting device 100 can be applied to each of the light emitting units 936. That is, a plurality of the pixels 201 are arranged along the longitudinal direction of the substrate. A direction 937 is a direction parallel to the axis of the photosensitive member 927. This column direction matches the direction of the axis of rotation of the photosensitive member 927. This direction 937 can also be referred to as the long-axis direction of the photosensitive member 927.

FIG. 15B shows a form in which the light emitting units 936 are arranged along the long-axis direction of the photosensitive member 927. FIG. 15C shows a form, which is a modification of the configuration of the light emitting units 936 shown in FIG. 15B, in which the light emitting units 936 are arranged in the column direction alternately between the first column and the second column. The light emitting units 936 are arranged at different positions in the row direction between the first column and the second column. In the first column, the plurality of light emitting units 936 are arranged apart from each other. In the second column, the light emitting unit 936 is arranged at the position corresponding to the space between the light emitting units 936 in the first column. Furthermore, in the row direction, the plurality of light emitting units 936 are arranged apart from each other. The arrangement of the light emitting units 936 shown in FIG. 15C can be referred to as, for example, an arrangement in a grid pattern, an arrangement in a staggered pattern, or an arrangement in a checkered pattern.

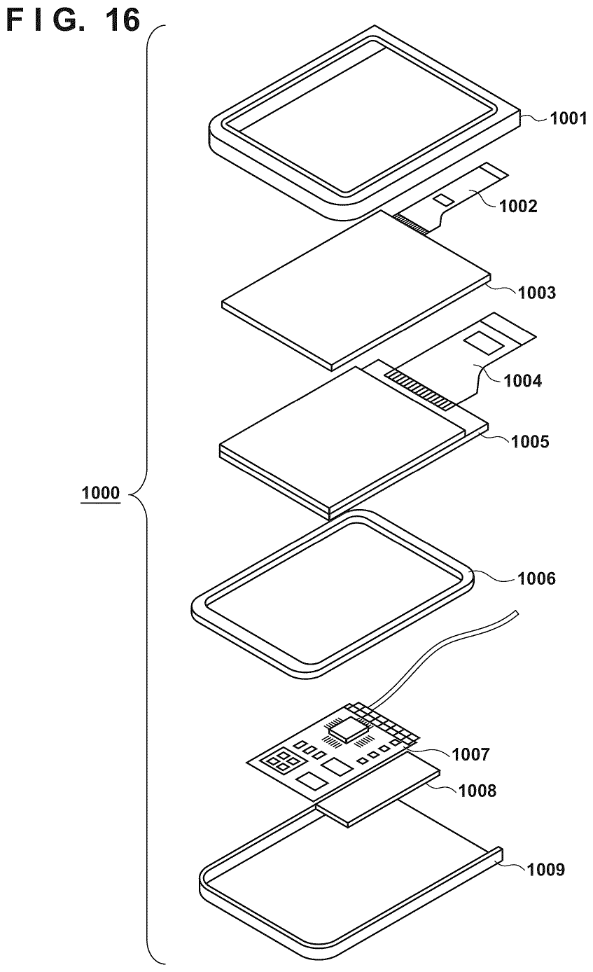

FIG. 16 is a schematic view showing an example of the display device using the light emitting device 100 according to this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. An active element such as a transistor is arranged on the circuit board 1007. The battery 1008 is unnecessary if the display device 1000 is not a portable apparatus. Even when the display device 1000 is a portable apparatus, the battery 1008 need not be provided at this position. The light emitting device 100 can be applied to the display panel 1005. The pixels 201 arranged in the light emitting device 100 functioning as the display panel 1005 are connected to the control circuit including the active element such as a transistor arranged on the circuit board 1007 and operate.

The display device 1000 shown in FIG. 16 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

FIG. 17 is a schematic view showing an example of the photoelectric conversion device using the light emitting device 100 according to this embodiment. A photoelectric conversion device 1100 can include a viewfinder 1101, a rear display 1102, an operation unit 1103, and a housing 1104. The photoelectric conversion device 1100 can also be called an image capturing device. The light emitting device 100 according to this embodiment can be applied to the viewfinder 1101 or the rear display 1102 as a display unit. In this case, the light emitting device 100 can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time in many cases, it is better to display the information as soon as possible. Therefore, the light emitting device 100 in which the pixel 201 including the light emitting element using the organic light emitting material such as an organic EL element is arranged may be used for the viewfinder 1101 or the rear display 1102. This is because the organic light emitting material has a high response speed. The light emitting device 100 using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also be automatically performed.

The light emitting device 100 may be applied to a display unit of an electronic apparatus. At this time, the display unit can have both a display function and an operation function. Examples of the portable terminal are a portable phone such as a smartphone, a tablet, and a head mounted display.

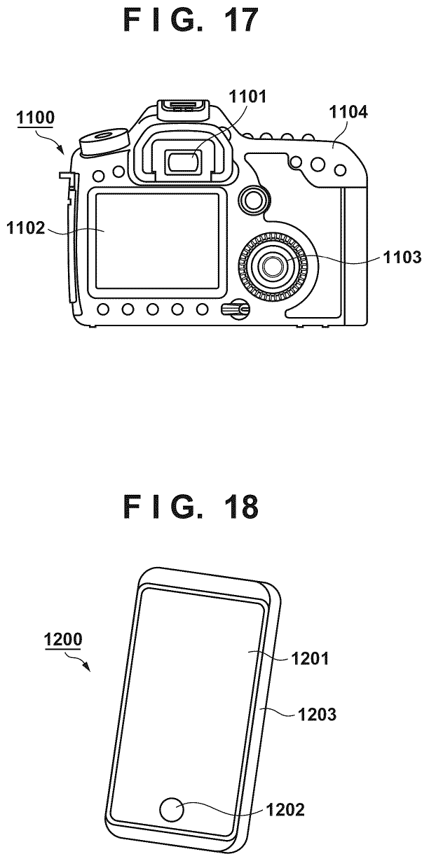

FIG. 18 is a schematic view showing an example of an electronic apparatus using the light emitting device 100 according to this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 100 according to this embodiment can be applied to the display unit 1201.

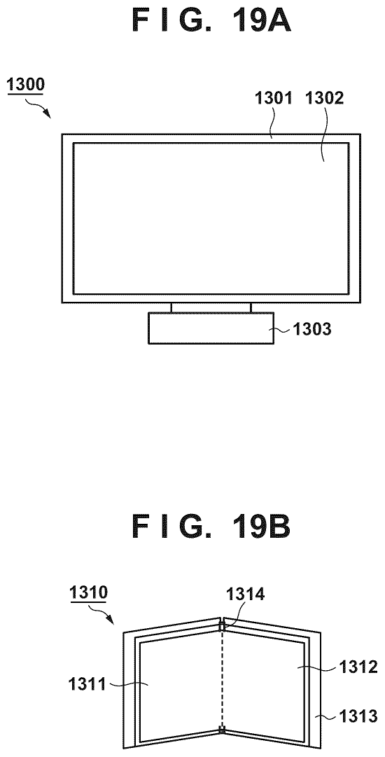

FIGS. 19A and 19B are schematic views showing examples of the display device using the light emitting device 100 according to this embodiment. FIG. 19A shows a display device such as a television monitor or a PC monitor. A display device 1300 includes a frame 1301 and a display unit 1302. The light emitting device 100 according to this embodiment can be applied to the display unit 1302. The display device 1300 can include a base 1303 that supports the frame 1301 and the display unit 1302. The base 1303 is not limited to the form shown in FIG. 19A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 19B is a schematic view showing another example of the display device using the light emitting device 100 according to this embodiment. A display device 1310 shown in FIG. 19B can be folded, and is a so-called foldable display device. The display device 1310 includes a first display unit 1311, a second display unit 1312, a housing 1313, and a bending point 1314. The light emitting device 100 according to this embodiment can be applied to each of the first display unit 1311 and the second display unit 1312. The first display unit 1311 and the second display unit 1312 can also be one seamless display device. The first display unit 1311 and the second display unit 1312 can be divided at the bending point. The first display unit 1311 and the second display unit 1312 can display different images, and can also display one image together.

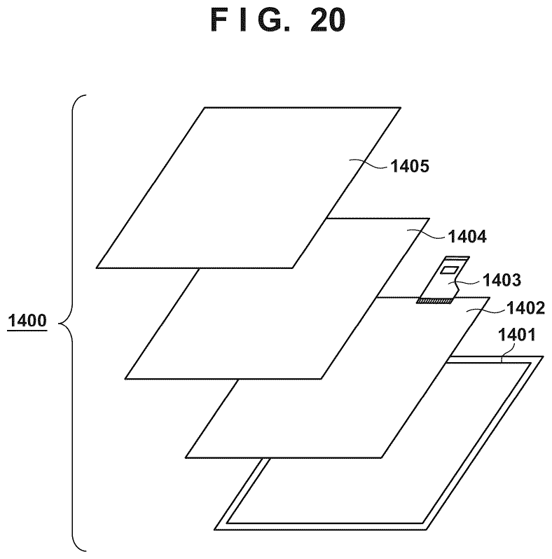

FIG. 20 is a schematic view showing an example of the illumination device using the light emitting device 100 according to this embodiment. An illumination device 1400 can include a housing 1401, a light source 1402, a circuit board 1403, an optical film 1404, and a light diffusing unit 1405. The light emitting device 100 according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination device can also include a cover on the outermost portion, as needed. The illumination device 1400 can include both or one of the optical film 1404 and the light diffusing unit 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to the light emitting device 100 functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicone.

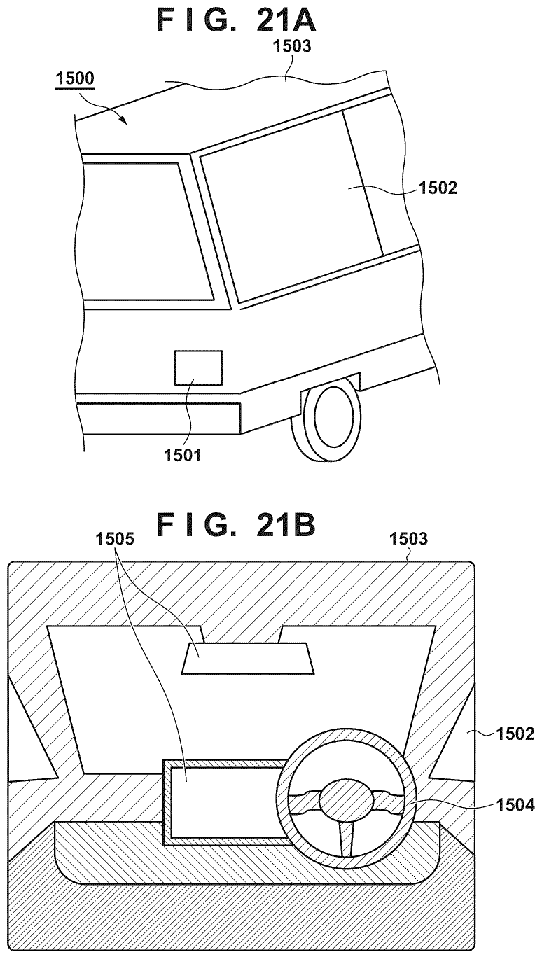

FIG. 21A is a schematic view of an automobile having a taillight as an example of a vehicle lighting appliance using the light emitting device 100 according to this embodiment. An automobile 1500 has a taillight 1501, and can have a form in which the taillight 1501 is turned on when performing a braking operation or the like. The light emitting device 100 according to this embodiment can be used as a headlight serving as a vehicle lighting appliance.

The light emitting device 100 according to this embodiment can be applied to the taillight 1501. The taillight 1501 can include a protection member for protecting the light emitting device 100 functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device 100 according to this embodiment may be used. In this case, the constituent materials of the electrodes and the like of the light emitting device 100 are formed by transparent members.

As shown in FIG. 21B, the automobile 1500 can include a steering wheel 1504 that controls the moving direction of the moving body (automobile), and a display unit 1505 that is mounted on the vehicle body 1503 and displays a map, the position of the moving body, a turning direction, the visual field on the rear side of the moving body, and the like. The light emitting device 100 according to this embodiment can be applied to the display unit 1505.

The automobile 1500 is an example of the moving body, and the moving body according to this embodiment includes one or both of a driving force generation unit that generates a driving force mainly used for moving the moving body and a rotating body mainly used for moving the moving body. The driving force generation unit can be an engine, a motor, or the like. The rotating body can be a tire, a wheel, a ship screw, an aircraft propeller or fan, or the like. More specifically, the moving body may be a bicycle, an automobile, a train, a ship, an aircraft, a drone, or the like. The moving body may include a main body and a lighting appliance provided in the main body. The lighting appliance may be used to make a notification of the current position of the main body. The lighting appliance may include the light emitting device 100 according to this embodiment. The display unit may include the light emitting device 100 according to this embodiment.

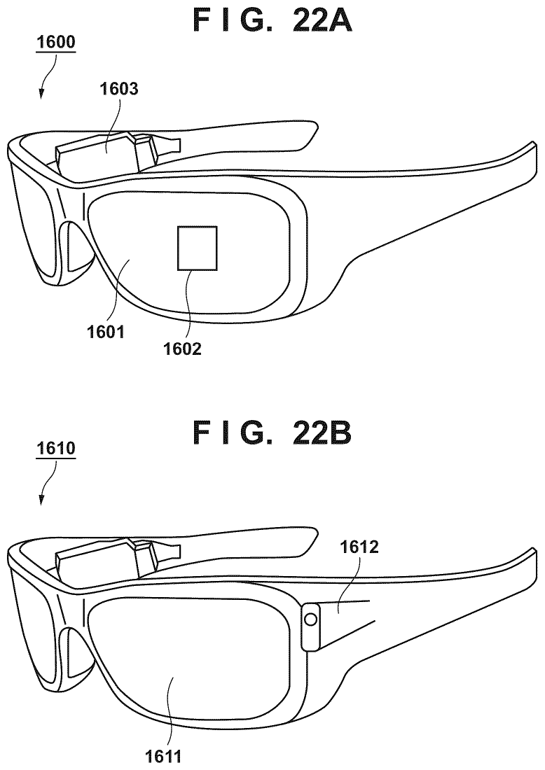

Further application examples of the light emitting device 100 according to this embodiment will be described with reference to FIGS. 22A and 22B. The light emitting device 100 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 22A. An image capturing device 1602 such as a CMOS sensor or an SPAD is provided on the surface side of a lens 1601 of the glasses 1600. In addition, the light emitting device 100 according to this embodiment is provided on the back surface side of the lens 1601.

The glasses 1600 further include a control device 1603. The control device 1603 functions as a power supply that supplies electric power to the image capturing device 1602 and the light emitting device 100 according to each embodiment. In addition, the control device 1603 controls the operations of the image capturing device 1602 and the light emitting device 100. An optical system configured to condense light to the image capturing device 1602 is formed on the lens 1601.

Glasses 1610 (smartglasses) according to one application example will be described with reference to FIG. 22B. The glasses 1610 include a control device 1612, and an image capturing device corresponding to the image capturing device 1602 and the light emitting device 100 are mounted on the control device 1612. The image capturing device in the control device 1612 and an optical system configured to project light emitted from the light emitting device 100 are formed in a lens 1611, and an image is projected onto the lens 1611. The control device 1612 functions as a power supply that supplies electric power to the image capturing device and the light emitting device 100, and controls the operations of the image capturing device and the light emitting device 100. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 100 according to this embodiment of the present disclosure can include an image capturing device including a light receiving element, and control a displayed image based on the line-of-sight information of the user from the image capturing device.

More specifically, the light emitting device 100 decides a first visual field region at which the user is gazing and a second visual field region other than the first visual field region based on the line-of-sight information. The first visual field region and the second visual field region may be decided by the control device of the light emitting device 100, or those decided by an external control device may be received. In the display region of the light emitting device 100, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 100, or those decided by an external control device may be received. The resolution of the region of higher priority may be controlled to be higher than the resolution of the region other than the region of higher priority. That is, the resolution of the region of relatively low priority may be low.

Note that Al may be used to decide the first visual field region or the region of higher priority. The Al may be a model configured to estimate the angle of the line of sight and the distance to a target ahead in the line of sight from the image of the eyeball using the image of the eyeball and the direction of actual viewing of the eyeball in the image as supervised data. The Al program may be held by the light emitting device 100, the image capturing device, or an external device. If the external device holds the Al program, it is transmitted to the light emitting device 100 via communication.

When performing display control based on line-of-sight detection, application to smartglasses further including an image capturing device configured to capture the outside is possible. The smartglasses can display captured outside information in real time.

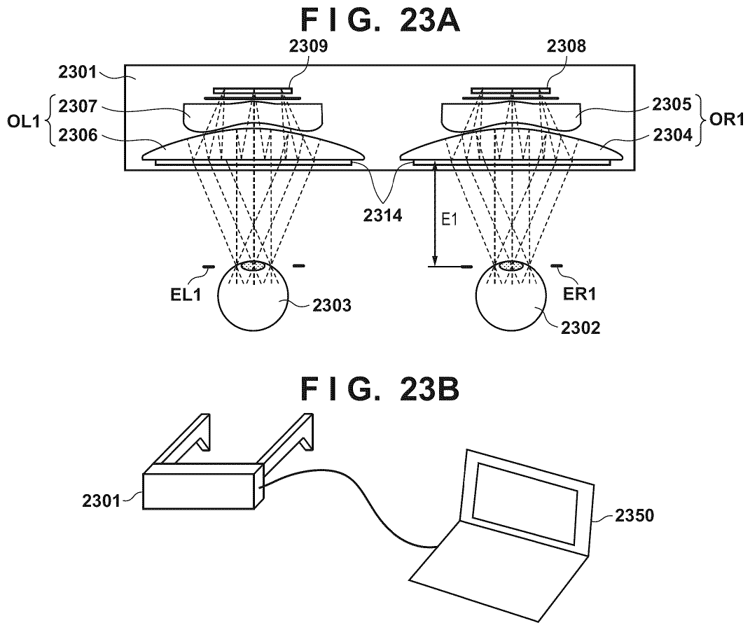

FIGS. 23A and 23B are schematic views of a head mounted display (HMD) 2301 as a display device according to an embodiment of the present disclosure. FIG. 23A is a schematic view showing the head mounted display and an observer wearing it. The HMD 2301 is worn on the observer's head. Reference numeral 2302 denotes the right eye of the observer, and reference numeral 2303 denotes the left eye of the observer. Display lenses 2304 and 2305 constitute an eyepiece optical system OR1 for the right eye, and display lenses 2306 and 2307 constitute an eyepiece optical system OL1 for the left eye. Each eyepiece optical system is a coaxial optical system constituted by multiple (two) display lenses. The observer's right eye 2302 is positioned at an exit pupil ER1 of the eyepiece optical system OR1 for the right eye, and the observer's left eye 2303 is positioned at an exit pupil EL1 of the eyepiece optical system OL1 for the left eye. The exit pupil ER1 is located at a distance E1 from the eyepiece optical system OR1 for the right eye. Similarly, the exit pupil EL1 is located at the distance E1 from the eyepiece optical system OL1 for the left eye. An optical film 2314 for lens protection, light condensing, and the like is provided on each of the surface (the surface on the right eye 2302 side) of the eyepiece optical system OR1 for the right eye and the surface (the surface on the left eye 2303 side) of the eyepiece optical system OL1 for the left eye.

Reference numerals 2308 and 2309 denote a display device for the right eye and a display device for the left eye, respectively. Each of these display devices may be the display device according to the embodiment. FIG. 23B is a schematic view showing an example where a display device according to an embodiment of the present disclosure is connected to an external device, and shows the outer appearances of the HMD 2301 and a personal computer 2350 connected thereto. Each display device displays a displayed image (original image) corresponding to an image signal output from the personal computer 2350. The HID 2301 and the personal computer 2350 are connected via a wired connection in this form, but may be connected via a wireless connection. The HMD 2301 may be a device that incorporates an image processing device and operates as a stand-alone device.

The eyepiece optical systems OR1 and OL1 guide light beams from the display devices 2308 and 2309 to the exit pupils ER1 and EL1, respectively, to project enlarged virtual images of the displayed images onto the right eye 2302 and left eye 2303 of the observer. This allows the observer to observe the displayed images (virtual images thereof) displayed on the display devices 2308 and 2309 through the eyepiece optical systems OR1 and OL1.

Although not shown, the HID 2301 may include a control device. The control device functions as a power supply for supplying power to the display devices 2308 and 2309, and controls the operations of the display devices 2308 and 2309.

According to one aspect of the present disclosure, a technique advantageous in improving display characteristic and suppressing the increase of power consumption can be provided.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-040485, filed Mar. 13, 2025, which is hereby incorporated by reference herein in its entirety.

What is claimed is:

1. A light emitting device in which a plurality of pixels including a first pixel are arranged on a main surface of a substrate, wherein
each of the plurality of pixels includes a first electrode, a second electrode arranged between the first electrode and the substrate, an organic functional layer arranged between the first electrode and the second electrode, a reflective layer arranged between the second electrode and the substrate, and an insulating layer arranged between the second electrode and the reflective layer,
the second electrode includes a first portion contacting the organic functional layer, and the insulating layer includes a second portion contacting the first portion,
in the first pixel, a film thickness of the first portion is larger than a film thickness of the second portion,
in the first pixel, the organic functional layer includes a light emitting layer containing a light emitting dopant, and
in a case where λ indicates a PL peak wavelength of the light emitting dopant, φ indicates a sum of a phase shift φr upon reflection in the reflective layer and a phase shift φs upon reflection in the first electrode (φ<0), and L indicates an optical distance between the reflective layer and the first electrode,
(λ/8)×(−(2φ/π)−1)<L<(λ/8)×(−(2φ/π)+1)
is satisfied.

2. The device according to claim 1, wherein
the plurality of pixels include a second pixel configured to emit light having a longer peak wavelength than a peak wavelength of light emitted by the first pixel, and
in the second pixel, a film thickness of the first portion is smaller than a film thickness of the second portion.

3. The device according to claim 1, wherein
a film thickness of the first portion is more than twice and less than ten times a film thickness of the second portion.

4. The device according to claim 1, wherein
a film thickness of the second portion in the first pixel is not less than 0.5 nm and not more than 5 nm.

5. The device according to claim 1, wherein
a film thickness of the first portion in the first pixel is not less than 5 nm and not more than 20 nm.

6. The device according to claim 1, wherein
a refractive index of the insulating layer is not more than 1.6.

7. The device according to claim 1, wherein
a refractive index of the second electrode is not less than 1.4.

8. The device according to claim 1, wherein
each of the plurality of pixels further includes a first metal layer arranged between the second electrode and the reflective layer and contacting the second electrode and the reflective layer, and a second metal layer arranged between the reflective layer and the substrate and contacting the reflective layer,
the reflective layer contains at least one of aluminum, copper-containing aluminum, an aluminum alloy containing aluminum-nickel, silver, and a silver alloy, and
the first metal layer and the second metal layer contain at least one of titanium, titanium nitride, a titanium alloy, tantalum, and a tantalum alloy.

9. The device according to claim 8, wherein
a surface of at least a part of an outer edge portion of the reflective layer, which faces a side opposite to the substrate, is in contact with the insulating layer.

10. The device according to claim 8, wherein
in each pixel, a film thickness of a third portion of the second electrode, which is in contact with the first metal layer, is larger than a film thickness of the first portion.

11. The device according to claim 8, wherein
in the first pixel, the second electrode includes a fourth portion located between the first portion and the third portion in contact with the first metal layer, and a fifth portion located between the third portion and an outer edge of the second electrode, and
in the first pixel, the fifth portion includes a portion which is higher than the fourth portion from the substrate.

12. The device according to claim 8, wherein
in each pixel, the first metal layer, the reflective layer, and the second metal layer constitute a pixel electrode connected to the second electrode, and
an isolating insulating portion is arranged between the pixel electrodes of respective pixels.

13. The device according to claim 1, wherein
in each pixel, an outer edge of a portion of the insulating layer, which is continuous from the second portion and has the same film thickness as the second portion, is located inside an outer edge of the reflective layer.

14. The device according to claim 1, wherein
in each pixel, an outer edge of a portion of the insulating layer, which is continuous from the second portion and has the same film thickness as the second portion, includes a portion located outside an outer edge of the reflective layer.

15. The device according to claim 1, wherein
in each pixel, a film thickness of the first portion is smaller than a film thickness of a portion adjacent to the first portion.

16. A display device comprising: the light emitting device according to claim 1; and a control circuit connected to the light emitting device.

17. A photoelectric conversion device comprising: an optical unit including a plurality of lenses; an image sensor configured to receive light having passed through the optical unit; and a display configured to display an image,
wherein the display includes the light emitting device according to claim 1.

18. An electronic apparatus comprising: a housing provided with a display; and a communication device provided in the housing and configured to perform external communication,
wherein the display includes the light emitting device according to claim 1.

19. An illumination device comprising: a light source; and at least one of a light diffusing portion and an optical film,
wherein the light source includes the light emitting device according to claim 1.

20. A moving body comprising: a main body; and a display provided in the main body,
wherein the display includes the light emitting device according to claim 1.
